(19) United States
(12) Patent Application Publication
(10) Pub. No.: US 2026/0122994 A1
(43) Pub. Date: Apr. 30, 2026

(54) SEMICONDUCTOR STACK, METHOD OF PRODUCING SEMICONDUCTOR STACK, AND HYDRIDE VAPOR PHASE EPITAXY APPARATUS

(71) Applicant: SUMITOMO CHEMICAL COMPANY, LIMITED, Tokyo (JP)

(72) Inventors: Shota KANEKI, Hitachi-shi (JP); Hajime Fujikura, Hitachi-shi (JP)

(73) Assignee: SUMITOMO CHEMICAL COMPANY, LIMITED, Tokyo (JP)

(21) Appl. No.: 19/373,345

(22) Filed: Oct. 29, 2025

(30) Foreign Application Priority Data
Oct. 31, 2024 (JP) 2024-191905

(51) Int. Cl. H10D 62/60; C23C 16/52; H01L 21/02; H10D 8/00; H10D 8/01; H10D 62/85; H10D 62/854

(52) U.S. Cl. CPC H10D 62/60; C23C 16/52; H10D 8/045; H10D 8/411; H10D 62/8503; H10D 62/854; H10P 14/24; H10P 14/3416; H10P 14/3444

(57) ABSTRACT

A semiconductor stack including a base substrate; and a PN junction structure including an n-type semiconductor layer on the base substrate and a p-type semiconductor layer on the n-type semiconductor layer, the n-type semiconductor layer being constituted from a group III nitride crystal containing an n-type impurity, the p-type semiconductor layer being constituted from a group III nitride crystal containing Mg as a p-type impurity, and the n-type semiconductor layer and the p-type semiconductor layer constituting a PN junction, or a PI junction structure including an i-type semiconductor layer on the base layer and the p-type semiconductor layer on the i-type semiconductor layer, the i-type semiconductor layer being constituted from a group III nitride, and the i-type semiconductor layer and the p-type semiconductor layer constituting a PI junction.

### BACKGROUND OF THE INVENTION

### Technical Field

The present disclosure relates to a semiconductor stack, a method of producing a semiconductor stack, and a hydride vapor phase epitaxy apparatus.

When providing a PN junction structure with an n-type semiconductor layer (n-type layer) constituted from a group III nitride crystal containing an n-type impurity and a p-type semiconductor layer (p-type layer) constituted from a group III nitride crystal containing magnesium (Mg) as a p-type impurity, there are cases where the n-type layer and the p-type layer are continuously grown by a hydride vapor phase epitaxy (HVPE) method in a single HVPE apparatus (see, for example, Patent document 1). The same applies when providing a PI junction structure with the p-type layer and a semiconductor layer (i-type layer) which is constituted from a group III nitride crystal and have non-conductivity. In the present disclosure, the concept of a “semiconductor layer having non-conductivity” means a semiconductor layer that has lower conductivity than a p-type layer.

### CITATION LIST

### Patent document

[Patent Document 1] JP 2018-207055 A

### SUMMARY OF THE INVENTION

An objective of the present disclosure is to obtain a high-quality semiconductor stack having a PN junction structure with an n-type layer and a p-type layer, or a PI junction structure with an i-type layer and a p-type layer.

According to one aspect of the present disclosure, there is provided a semiconductor stack including:
a base substrate; and
a PN junction structure including an n-type semiconductor layer on the base substrate and a p-type semiconductor layer on the n-type semiconductor layer, the n-type semiconductor layer being constituted from a group III nitride crystal containing an n-type impurity, the p-type semiconductor layer being constituted from a group III nitride crystal containing Mg as a p-type impurity, and the n-type semiconductor layer and the p-type semiconductor layer constituting a PN junction, or
a PI junction structure including an i-type semiconductor layer on the base substrate and the p-type semiconductor layer on the i-type semiconductor layer, the i-type semiconductor layer being constituted from a group III nitride, and the i-type semiconductor layer and the p-type semiconductor layer constituting a PI junction,
wherein Mg concentration in the n-type semiconductor layer or the i-type semiconductor layer is less than 1×10¹⁶ cm⁻³, and
Fe concentration at an interface of the PN junction or the PI junction is 2×10¹⁵ cm⁻³ or less.

According to another aspect of the present disclosure, there is provided a method of producing a semiconductor stack, the method including:
(a) placing a base substrate in a first space and placing an Mg source in a gas generator placed in a second space different from the first space, the first space being for crystal growth, the first and second spaces being spaces inside a reaction vessel provided in a hydride vapor phase epitaxy apparatus; then
(b) performing either (b1) supplying, to the base substrate in the first space, a halide of a group III element and a nitriding agent while also supplying an n-type impurity-containing gas, and growing an n-type semiconductor layer on the base substrate, the n-type semiconductor layer being constituted from a group III nitride crystal containing an n-type impurity, or (b2) supplying, to the base substrate in the first space, a halide of a group III element and a nitriding agent, and growing an i-type semiconductor layer on the base substrate, the i-type semiconductor layer being constituted from a group III nitride crystal; and
(c) supplying, to the base substrate in the first space, a halide of a group III element and a nitriding agent while also supplying an Mg-containing gas from a nozzle provided at a downstream end of a gas supply pipe connected to a downstream side of the gas generator, the Mg-containing gas being generated either by supplying a halogen-containing gas to the Mg source in the gas generator and reacting between the halogen-containing gas and the Mg source, or by vaporizing the Mg source in the gas generator, and growing a p-type semiconductor layer on the base substrate, the p-type semiconductor layer being constituted from a group III nitride crystal containing Mg,
wherein the generation of the Mg-containing gas is started before the start of the (c), and the Mg-containing gas generated before the start of the (c) is discharged to outside the reaction vessel through a vent pipe connected to the gas supply pipe without passing through the first space, and
the Mg-containing gas generated during execution of the (c) is supplied to the base substrate in the first space from the nozzle by switching a flow path of the Mg-containing gas by controlling a flow-path switching valve provided at a site where the gas supply pipe is connected with the vent pipe.

According to another aspect of the present disclosure, there is provided a hydride vapor phase epitaxy apparatus including:
a reaction vessel including, on an inside of the reaction vessel, a first space in which a base substrate is placed and crystal growth is performed and a second space that is heated to a temperature different from a temperature of the first space;
a gas generator, which is placed in the second space and in which a dopant source is placed;
a gas supply pipe connected to a downstream end of the gas generator;
a nozzle connected to a downstream end of the gas supply pipe, the nozzle being configured to supply a dopant-containing gas generated in the gas generator toward the base substrate in the first space;
a vent pipe connected to the gas supply pipe;
a flow-path switching valve placed in the second space, the flow-path switching valve being configured to switch a flow path of the dopant-containing gas generated in the gas generator so as to discharge the dopant-containing gas to outside the reaction vessel through the vent pipe without passing through the first space; and
a controller configured to control the flow-path switching valve,
wherein inside the reaction vessel, there are provided, as flow paths of the dopant-containing gas generated in the gas generator, a first flow path in which the dopant-containing gas is supplied to the base substrate in the first space through the gas supply pipe and the nozzle, and a second flow path in which the dopant-containing gas is discharged to outside the reaction vessel through the gas supply pipe and the vent pipe without passing through the first space, and
the controller is configured to control the flow-path switching valve to switch between the first flow path and the second flow path.

According to the present disclosure, a high-quality semiconductor stack, which has a PN junction structure with an n-type layer and a p-type layer, or a PI junction structure with an i-type layer and a p-type layer, can be obtained.

### BRIEF DESCRIPTION OF THE DRAWINGS

FIG. 1 is a view illustrating an example of a schematic cross section of a semiconductor stack according to an embodiment of the present disclosure.

FIG. 2 is a schematic configuration view of an HVPE apparatus and illustrates a state during execution of a crystal growth process within a reaction vessel.

FIG. 3 is a schematic configuration view of an HVPE apparatus and illustrates a state in which a furnace opening of a reaction vessel is open.

FIG. 4 is a view illustrating an example of a schematic cross section of a semiconductor stack according to a modification of an embodiment of the present disclosure.

FIG. 5A is a view illustrating an example of a schematic cross section of a semiconductor stack according to another modification of an embodiment of the present disclosure.

FIG. 5B is a view illustrating an example of a schematic cross section of a semiconductor stack according to still another modification of an embodiment of the present disclosure.

FIG. 5C is a view illustrating an example of a schematic cross section of a semiconductor stack according to yet another modification of an embodiment of the present disclosure.

FIG. 6 is a schematic configuration view of a conventional HVPE apparatus and illustrates a state during execution of a crystal growth process within a reaction vessel.

### DESCRIPTION OF EMBODIMENTS

### Findings Obtained by Inventors

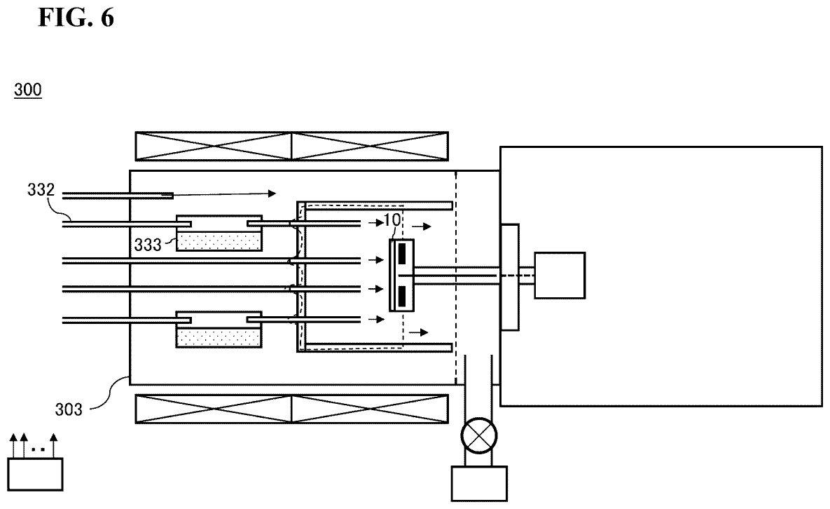

When providing, on a base substrate, a PN junction structure with an n-type layer and a p-type layer, or providing, on a base substrate, a PI junction structure with an i-type layer and a p-type layer, sometimes an HVPE apparatus 300 such as that illustrated in FIG. 6 is used to continuously grow the n-type layer or i-type layer, and the p-type layer by an HVPE method.

When growing, by the HVPE method, a p-type layer containing magnesium (Mg) as a p-type impurity, metallic Mg or magnesium nitride (Mg₃N₂) is sometimes used as the Mg source (dopant source). For example, an Mg-containing gas is generated by vaporizing an Mg source in a gas generator 333 placed inside a reaction vessel 303 provided in the HVPE apparatus 300, and the Mg-containing gas is supplied, together with raw material gases (a group III source-containing gas and a nitriding agent), to a base substrate 10 inside the reaction vessel 303 to grow the p-type layer. When supplying the Mg-containing gas to the base substrate 10, a carrier gas may be flowed together with the Mg-containing gas.

However, in the case where metallic Mg or Mg₃N₂ is used as the Mg source, once the temperature inside the reaction vessel 303 reaches a predetermined temperature, the Mg source placed inside the reaction vessel 303 constantly vaporizes and the Mg-containing gas is continuously generated. Therefore, when the n-type layer or i-type layer, and the p-type layer are continuously grown using the HVPE apparatus 300 by the HVPE method, an Mg-containing gas is generated even during growth of the n-type layer or the i-type layer, and the Mg-containing gas is supplied to the base substrate 10 inside the reaction vessel 303 even if no carrier gas is flowed. As a result, a certain amount of Mg is incorporated into the n-type layer or the i-type layer.

When growing a p-type layer containing Mg by the HVPE method, magnesium fluoride (MgF₂) or magnesium oxide (MgO) is sometimes used as the Mg source (dopant source). In the case where MgF₂ or MgO is used as the Mg source, supply of a halogen-containing gas from a gas supply pipe 332 to the Mg source in the gas generator 333 placed inside the reaction vessel 303 is started in conjunction with the start of growth of the p-type layer; an Mg-containing gas is generated by reaction between the halogen-containing gas and the Mg source; the Mg-containing gas is supplied, together with the raw material gases, to the base substrate 10 inside the reaction vessel 303; and the p-type layer is grown. Then, by stopping the supply of the halogen-containing gas at the termination of the growth of the p-type layer, generation of the Mg-containing gas ends and supply of the Mg-containing gas to the base substrate 10 is stopped.

In the case where MgF₂ or MgO is used as the Mg source, even when the n-type layer or i-type layer, and the p-type layer are continuously grown using the HVPE apparatus 300, the aforementioned problem that Mg is incorporated into the n-type layer or the i-type layer does not arise.

However, in the HVPE apparatus 300, components such as the gas supply pipe 332 that supplies the halogen-containing gas, and a flow rate controller and valves (both not illustrated) provided to the gas supply pipe 332, include members constituted from stainless steel (SUS) (hereinafter also referred to as “SUS members”). Accordingly, at the beginning of flowing the halogen-containing gas (for example, from the start of supplying the halogen-containing gas until surfaces of the SUS members become stabilized), iron (Fe) originating from SUS is discharged at a high concentration and is incorporated into the crystal. In the present disclosure, “stabilization of a surface of an SUS member” means that a surface of an SUS member that can be contacted by the halogen-containing gas is chemically stabilized, for example by being terminated with halogen, and is modified into a state in which release of impurities such as Fe is unlikely to occur.

After a certain period has elapsed from the start of supplying the halogen-containing gas and the surfaces of the SUS members have been stabilized, Fe originating from the SUS members is scarcely discharged. However, when the n-type layer or i-type layer, and the p-type layer containing Mg are continuously grown in this order using the HVPE apparatus 300, the supply of the halogen-containing gas is stopped at timings other than during growth of the p-type layer (for example, during growth of the n-type layer or the i-type layer). When the supply of the halogen-containing gas is stopped, the stabilized state of the surfaces of the SUS members is cancelled.

Therefore, when the n-type layer or i-type layer, and the p-type layer are continuously grown in this order using the HVPE apparatus 300, Fe originating from SUS is discharged at a high concentration at an initial stage of growth of the p-type layer and is incorporated into the crystal. As a result, Fe concentration at an interface between the n-type layer and the p-type layer (PN junction interface) or at an interface between the i-type layer and the p-type layer (PI junction interface) becomes high.

As described above, when the n-type layer or i-type layer, and the p-type layer containing Mg are continuously grown using the HVPE apparatus 300 by the HVPE method, to provide, on the base substrate 10, a PN junction structure or a PI junction structure, it has been difficult to achieve both suppression of Mg incorporation in the n-type layer or the i-type layer and reduction of Fe concentration at the PN junction interface or the PI junction interface.

It may also be conceivable to continuously grow, within the same metal-organic chemical vapor deposition (MOCVD) apparatus by an MOCVD method, the n-type layer or i-type layer, and the p-type layer containing Mg. However, in the n-type layer, i-type layer, and p-type layer grown by the MOCVD method, carbon (C), which is an unintended impurity originating from various organic source gases used for crystal growth, is incorporated at a high concentration.

It may also be conceivable to continuously grow, by a flux method using an alkali metal such as sodium (Na) or lithium (Li) as a flux, the n-type layer or i-type layer, and the p-type layer containing Mg. However, it is difficult to produce a multilayered stack such as a PN junction structure or a PI junction structure with the n-type layer or i-type layer, and the p-type layer by the flux method. Moreover, in the n-type layer, i-type layer, and p-type layer grown by the flux method, unintended impurities such as Na, Li, and oxygen (O), originating from the process, are incorporated at high concentrations.

Thus, when the n-type layer, the i-type layer, and the p-type layer are grown by the MOCVD method, the flux method, or the like, it has been difficult to obtain high-purity crystals in which the n-type layer, the i-type layer, and the p-type layer have extremely low concentrations of unintended impurities such as C, O, Na, and Li.

It may also be conceivable to continuously grow, by an ammonothermal method, the n-type layer or i-type layer, and the p-type layer containing Mg. However, the ammonothermal method is chiefly a technique for obtaining bulk crystals, and it is difficult to grow thin films. This is because phenomena such as so-called melt-back in which gallium nitride (GaN) dissolves into a gallium (Ga) solution, and growth during temperature/pressure rise, cannot be neglected. Therefore, by the ammonothermal method, it is difficult to produce thin n-type, i-type, and p-type layers, and, for similar reasons, it is also difficult to produce a multilayered stack such as a PN junction structure or a PI junction structure with the n-type layer or i-type layer, and the p-type layer. Furthermore, in the n-type layer, i-type layer, and p-type layer grown by the ammonothermal method, oxygen (O), which is an unintended impurity originating from the process, is incorporated at a high concentration.

In view of the foregoing, the inventors focused on the new technical problem of simultaneously achieving suppression of Mg incorporation in the n-type layer or the i-type layer and reduction of Fe concentration at the PN junction interface or the PI junction interface in a PN junction structure or a PI junction structure formed by continuously growing, by the HVPE method, the n-type layer or i-type layer, and the p-type layer containing Mg, and have made intensive studies on solutions thereto.

As a result, the inventors have found that, in an HVPE apparatus, regardless of whether the Mg source is metallic Mg, Mg₃N₂, MgF₂, or MgO, by starting generation of Mg-containing gas before the start of growth of the p-type layer and, moreover, by discharging to outside the reaction vessel the Mg-containing gas generated before the start of growth of the p-type layer without supplying it to the base substrate inside the reaction vessel, both suppression of Mg incorporation in the n-type layer or the i-type layer and reduction of Fe concentration at the PN junction interface or the PI junction interface can be simultaneously achieved.

The inventors have further made intensive studies on means for implementing, in an HVPE apparatus, a technique in which generation of an Mg-containing gas is started before the start of growth of the p-type layer and the Mg-containing gas generated before the start of growth of the p-type layer is discharged to outside the reaction vessel without supplying it to the base substrate inside the reaction vessel.

As a result, it has been found that, in a conventional HVPE apparatus (for example, the HVPE apparatus in JP 2023-110417 A) including a gas generator that accommodates an Mg-source, a gas supply pipe connected to a downstream side of the gas generator, and a nozzle connected to a downstream end of the gas supply pipe to supply Mg-containing gas to a base substrate inside a reaction vessel, the above technique can be implemented by connecting a vent pipe to the gas supply pipe and providing a flow-path switching valve at a site where the gas supply pipe is connected with the vent pipe. It has also been found that, by forming the flow-path switching valve from a material that withstands contact with a high-temperature Mg-containing gas and does not react with high-temperature Mg, the above technique can be implemented even in an HVPE apparatus in which the flow-path switching valve is placed in a region heated to a high temperature.

The present disclosure is based on the above findings obtained by the inventors. Note that, in the following disclosure, as long as the “n-type layer” and the “p-type layer” respectively contain an n-type impurity and a p-type impurity at predetermined concentrations, the n-type impurity and the p-type impurity may be in either an activated state or an inactive state. In addition, the “carrier concentration” in the following disclosure mainly exemplifies a carrier concentration when these impurities are activated.

### Embodiments Of The Present Disclosure

The following describes an embodiment of the present disclosure with reference to the drawings.

### 1 Configuration of Semiconductor Stack

A semiconductor stack 1 according to this embodiment is configured as a disk-shaped stack used when manufacturing a semiconductor device. Specifically, the semiconductor stack 1 is configured, for example, as a stack for manufacturing a PN junction diode as a semiconductor device.

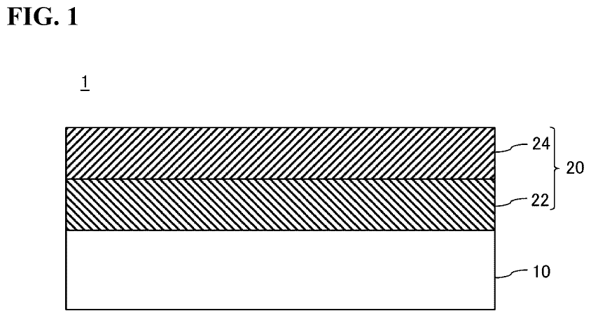

As illustrated in FIG. 1, the semiconductor stack 1 includes, for example, a base substrate 10 and a PN junction structure 20.

### Base Substrate

As the base substrate 10, a free-standing substrate constituted from a single crystal of a group III nitride semiconductor, for example a free-standing substrate constituted from a single crystal of gallium nitride (GaN) (GaN free-standing substrate), can be used.

The surface orientation of a principal surface (upper surface) of the base substrate 10 is, for example, the (0001) plane (+c plane, Ga-polar surface). The term “upper surface of the base substrate 10” as used herein means the surface on which the PN junction structure is to be provided among the two principal surfaces of the base substrate 10. The GaN crystal constituting the base substrate 10 may have a predetermined off-angle with respect to the principal surface of the base substrate 10. The off-angle is an angle formed by a normal direction of the principal surface of the base substrate 10 and a principal axis (c-axis) of the GaN crystal constituting the base substrate 10. The off-angle of the base substrate 10 is, for example, 0° or more and 1.2° or less

The principal surface of the base substrate 10 is an epi-ready surface, and the root-mean-square roughness (RMS) of the principal surface of the base substrate 10 is, for example, 10 nm or less, preferably 1 nm or less. Here, “RMS” refers to an RMS measured over a 20-μm-square area by an atomic force microscope (AFM).

The diameter of the base substrate 10 is not particularly limited, but is, for example, 25 mm or more, preferably 50 mm or more, and more preferably 100 mm or more. The diameter of the base substrate 10 is 25 mm or more, preferably 50 mm or more, and more preferably 100 mm or more, and therefore, productivity of semiconductor devices can be improved.

The thickness of the base substrate 10 is, for example, 150 μm or more and 2 mm or less. The thickness of the base substrate 10 is 150 μm or more, and therefore, mechanical strength of the base substrate 10 can be ensured and the base substrate 10 can be made free-standing.

The conductivity type of the base substrate 10 is not particularly limited and is, for example, n-type. Examples of n-type impurities contained in the base substrate 10 include silicon (Si) and germanium (Ge). In this embodiment, for example, the n-type impurity in the base substrate 10 is Si, and Si concentration in the base substrate 10 is 1×10¹⁸ cm⁻³ or more and 3×10²⁰ cm⁻³ or less.

### PN Junction Structure

The PN junction structure 20 is provided on the base substrate 10. The PN junction structure 20 includes an n-type semiconductor layer 22 (hereinafter “n-type layer 22”) constituted from a group III nitride containing an n-type impurity, and a p-type semiconductor layer 24 (hereinafter “p-type layer 24”) constituted from a group III nitride containing magnesium (Mg) as a p-type impurity. In the PN junction structure 20, a PN junction is constituted by the n-type layer 22 and the p-type layer 24.

### N-Type Semiconductor Layer

The n-type layer 22 is provided on the base substrate 10 and is constituted from a group III nitride crystal containing an n-type impurity. The n-type layer 22 is, for example, constituted from single-crystal GaN containing an n-type impurity. The n-type layer 22 is provided by, for example, epitaxially growing a group III nitride crystal on the base substrate 10 by the HVPE method. Examples of the n-type impurity include Si and Ge.

N-type impurity concentration in the n-type layer 22 is, for example, 3×10¹⁹ cm⁻³ or less, and preferably 5×10¹⁶ cm⁻³ or less. The n-type impurity concentration in the n-type layer 22 is 3×10¹⁹ cm⁻³ or less, and therefore, degradation of crystallinity of the n-type layer 22 is suppressed. N-type impurity concentration in the n-type layer 22 is 5×10¹⁶ cm⁻³ or less, and therefore, degradation of crystallinity of the n-type layer 22 is reliably suppressed. Note that, when the n-type impurity concentration in the n-type layer 22 exceeds 3×10¹⁹ cm⁻³, crystallinity of the n-type layer 22 may degrade.

A lower limit of n-type impurity concentration in the n-type layer 22 is not particularly limited as long as sufficient n-type impurity to obtain a necessary carrier concentration is contained. A current lower detection limit (detection limit) for the n-type impurity in SIMS depth profile analysis (hereinafter also simply referred to as “SIMS”) is 5×10¹⁴ cm⁻³. Accordingly, the n-type impurity concentration in the n-type layer 22 is, for example, 5×10¹⁴ cm⁻³ or more.

As carrier concentration in the n-type layer 22 becomes lower, a phenomenon called punch-through is more likely to occur and pressure resistance characteristics may deteriorate. Therefore, it is preferable to set, as appropriate, the thickness of the n-type layer 22 to a predetermined thickness (hereinafter “required thickness”) at which no punch-through occurs, according to the n-type impurity concentration. Here, when the n-type impurity concentration is 3×10¹⁹ cm⁻³, the above required thickness is about 5 μm. When the n-type impurity concentration is 5×10¹⁴ cm⁻³, the above required thickness is about 200 μm. From the foregoing, when the n-type impurity concentration in the n-type layer 22 is within the above range (×10¹⁴ cm⁻³ or more and 3×10¹⁹ cm⁻³ or less), it is preferable that the thickness of the n-type layer 22 be 5 μm or more and 200 μm or less. When the thickness of the n-type layer 22 is made greater than the above required thickness (i.e., with a surplus thickness), productivity may decrease in proportion to the magnitude of the surplus, and device characteristics may deteriorate due to the surplus thickness. Therefore, it is preferable to determine the magnitude of the surplus thickness of the n-type layer 22 in view of these issues.

In this embodiment, when providing the PN junction structure 20, using, for example, an HVPE apparatus 200 described later, generation of an Mg-containing gas is started before the start of growth of the p-type layer 24 (for example, while the n-type layer 22 is being grown or before the start of growth of the n-type layer 22), and the Mg-containing gas generated before the start of growth of the p-type layer 24 is discharged to outside a reaction vessel 203 provided in the HVPE apparatus 200 without passing through a first space 201a inside the reaction vessel 203 (i.e., without supplying it to the base substrate 10 in the reaction vessel 203), as described later. Therefore, even when an Mg-containing gas is generated while the n-type layer 22 is being grown when the n-type layer 22 and the p-type layer 24 are continuously grown using the same HVPE apparatus 200, incorporation of Mg into the n-type layer 22 is suppressed.

Specifically, Mg concentration in the n-type layer 22 measured by SIMS is less than 1×10¹⁶ cm⁻³. Preferably, Mg concentration in the n-type layer 22 is less than the detection limit of SIMS. A current SIMS detection limit for Mg is 5×10¹⁴ cm⁻³.

When Mg concentration is less than 1×10¹⁶ cm⁻³, carrier concentration in the n-type layer 22 can be reliably 1×10¹⁶ cm⁻³ or more by setting n-type impurity concentration in the n-type layer 22 within the above range. When Mg concentration is less than 5×10¹⁴ cm⁻³, carrier concentration in the n-type layer 22 can be reliably 5×10¹⁴ cm⁻³ or more by setting n-type impurity concentration in the n-type layer 22 within the above range.

Moreover, by discharging the Mg-containing gas generated before the start of growth of the p-type layer 24 to outside the reaction vessel 203 without passing through the first space 201a inside the reaction vessel 203 provided in the HVPE apparatus 200 described later, even when an Mg-containing gas is generated while the n-type layer 22 is being grown, incorporation of Fe originating from SUS members into the n-type layer 22 is also suppressed.

Specifically, Fe concentration in the n-type layer 22 measured by SIMS is, for example, 2×10¹⁵ cm⁻³ or less. Preferably, Fe concentration in the n-type layer 22 is less than the detection limit of SIMS. A current SIMS detection limit for Fe is 5×10¹⁴ cm⁻³. Further, Fe concentration in the n-type layer 22 measured by the isothermal capacitance transient spectroscopy (ICTS) method is, for example, 1×10¹³ cm⁻³ or less, and preferably 3×10¹² cm⁻³ or less.

The n-type layer 22 is grown on the base substrate 10 by the HVPE method as described later. Therefore, as compared with a case in which the n-type layer 22 is grown by the MOCVD method, incorporation of C into the n-type layer 22 is suppressed. Also, unlike a case in which the n-type layer 22 is grown by the flux method, the n-type layer 22 substantially contains no alkali metal elements such as Na and Li.

In addition, in this embodiment, when the n-type layer 22 is grown by the HVPE method, the HVPE apparatus 200 described later is used, for example. Therefore, incorporation of unintended impurities other than the n-type impurity into the n-type layer 22 is also suppressed.

Specifically, C concentration and O concentration in the n-type layer 22 are each less than the detection limit of SIMS. Current SIMS detection limits for C and O are each 5×10¹⁵ cm⁻³.

Moreover, boron (B) concentration in the n-type layer 22 is less than the detection limit of SIMS. A current SIMS detection limit for B is 1×10¹⁵ cm⁻³.

Furthermore, in the n-type layer 22 of this embodiment, none of arsenic (As), chlorine (Cl), phosphorus (P), fluorine (F), Na, Li, potassium (K), tin (Sn), titanium (Ti), manganese (Mn), chromium (Cr), molybdenum (Mo), tungsten (W), and nickel (Ni) is detected. That is, concentrations of these elements in the n-type layer 22 are less than SIMS detection limits. Current SIMS detection limits for these elements are as follows.
As: 5×10¹² cm⁻³
Cl: 1×10¹⁴ cm⁻³
P: 2×10¹⁵ cm⁻³
F: 4×10¹³ cm⁻³
Na: 5×10¹¹ cm⁻³
Li: 5×10¹¹ cm⁻³
K: 2×10¹² cm⁻³
Sn: 1×10¹³ cm⁻³
Ti: 1×10¹² cm⁻³
Mn: 5×10¹² cm⁻³
Cr: 7×10¹³ cm⁻³
Mo: 1×10¹⁵ cm⁻³
W: 3×10¹⁶ cm⁻³
Ni: 1×10¹⁴ cm⁻³

Thus, concentrations of impurities other than the n-type impurity in the n-type layer 22 are less than SIMS detection limits. In other words, the crystal constituting the n-type layer 22 is of high purity.

### P-Type Semiconductor Layer

The p-type layer 24 is provided, for example, on the n-type layer 22 (i.e., above the base substrate 10) and is constituted from a group III nitride crystal containing Mg as a p-type impurity. The p-type layer 24 is, for example, constituted from single-crystal GaN containing Mg. The p-type layer 24 is provided by, for example, epitaxially growing a group III nitride crystal on the n-type layer 22 by the HVPE method.

Mg concentration as the p-type impurity in the p-type layer 24 is, for example, 1×10¹⁶ cm⁻³ or more and 5×10²⁰ cm⁻³ or less.

When Mg concentration is, for example, less than 1×10¹⁶ cm⁻³, a necessary carrier concentration may not be obtained. Mg concentration is, for example, 1×10¹⁶ cm⁻³ or more, and therefore, the necessary carrier concentration can be obtained. When Mg concentration exceeds, for example, 5×10²⁰ cm⁻³, crystallinity of the p-type layer 24 may deteriorate. Mg concentration is, for example, 5×10²⁰ cm⁻³ or less, and therefore, deterioration of the crystallinity of the p-type layer 24 is suppressed.

In this embodiment, when growing the p-type layer 24, using, for example, the HVPE apparatus 200 described later, generation of an Mg-containing gas is started before the start of growth of the p-type layer 24, and growth of the p-type layer 24 is started while keeping generation of the Mg-containing gas continued without stopping, as described later. Therefore, growth of the p-type layer 24 can be started with surfaces of SUS members, which can be contacted by the halogen-containing gas necessary for generation of the Mg-containing gas, being in a stabilized state. As a result, incorporation of Fe into the p-type layer 24 is suppressed.

Specifically, Fe concentration in the p-type layer 24 measured by SIMS is, for example, 2×10¹⁵ cm⁻³ or less. Preferably, Fe concentration in the p-type layer 24 is less than the detection limit of SIMS. A current SIMS detection limit for Fe is 5×10¹⁴ cm⁻³. Further, Fe concentration in the n-type layer 22 measured by the ICTS method is, for example, 1×10¹³ cm⁻³ or less, and preferably 3×10¹² cm⁻³ or less.

As described later, the p-type layer 24 is grown on the n-type layer 22 by the HVPE method. Therefore, as compared with a case where the p-type layer 24 is grown by the MOCVD method, incorporation of C into the p-type layer 24 is suppressed. Also, unlike a case where the p-type layer 24 is grown by the flux method, the p-type layer 24 substantially contains no alkali metal elements such as Na and Li.

In addition, in this embodiment, when the p-type layer 24 is grown by the HVPE method, the HVPE apparatus 200 described later is used, for example. Therefore, incorporation of unintended impurities other than Mg as the p-type impurity (other than Mg and F, when F is included as described later) into the p-type layer 24 is suppressed.

Specifically, C concentration, O concentration, and Si concentration in the p-type layer 24 are each less than the detection limit of SIMS. Current SIMS detection limits for C, O, and Si are 5×10¹⁵ cm⁻³, 5×10¹⁵ cm⁻³, and 1×10¹⁵ cm⁻³, respectively.

Moreover, B concentration in the p-type layer 24 is less than the detection limit of SIMS. A current SIMS detection limit for B is 1×10¹⁵ cm⁻³.

Further, F concentration in the p-type layer 24 is less than the detection limit of SIMS. A current SIMS detection limit for F is 4×10¹³ cm⁻³.

Furthermore, in the p-type layer 24 of this embodiment, none of As, Cl, P, Na, Li, K, Sn, Ti, Mn, Cr, Mo, W, and Ni is detected. That is, concentrations of these elements in the p-type layer 24 are less than SIMS detection limits. Note that current SIMS detection limits for these elements at the p-type layer 24 are the same as those for these elements in the n-type layer 22.

Thus, concentrations of impurities other than Mg as the p-type impurity (concentrations of impurities other than Mg and F, when fluorine (F) is included as described later) in the p-type layer 24 are less than SIMS detection limits. In other words, the crystal constituting the p-type layer 24 is of high purity.

Note that, when the p-type layer 24 is grown by the HVPE method using MgF₂ as the Mg source, the p-type layer 24 contains F originating from the Mg source.

When the p-type layer 24 contains F, F concentration in the p-type layer 24 measured by SIMS is, for example, 1×10¹⁴ cm⁻³ or less. By allowing the p-type layer 24 to contain a trace amount of F, an activation ratio of Mg in the p-type layer 24 is improved. Here, the term “activation ratio of Mg” refers to a ratio, with respect to Mg concentration in the p-type layer 24, of carrier concentration in the p-type layer 24 at room temperature (23° C.), expressed in percent.

F concentration in the p-type layer 24 is preferably 1×10¹⁶ cm⁻³ or less. This suppresses carrier passivation caused by excessive incorporation of F.

In the MOCVD method, bis(cyclopentadienyl)magnesium (Cp₂Mg) is used as an Mg source, for example. Therefore, when the p-type layer 24 is grown by the MOCVD method, not only C ends up being incorporated at a high concentration into the p-type layer 24, but it is also difficult to allow the p-type layer 24 to contain F.

In contrast, in this embodiment, the p-type layer 24 is grown by the HVPE method using, for example, the HVPE apparatus 200 described later. This suppresses incorporation of impurities other than Mg and F into the p-type layer 24. That is, the p-type layer 24 of this embodiment contains Mg and a trace amount of F and substantially contains no impurities other than Mg and F. Therefore, the activation ratio of Mg in the p-type layer 24 of this embodiment is not less than an activation ratio of Mg in a p-type layer grown by the MOCVD method.

Specifically, in this embodiment, when Mg concentration in the p-type layer 24 is less than 1×10¹⁸ cm⁻³, the activation ratio of Mg in the p-type layer 24 is, for example, not less than 11%.

Further, in this embodiment, when Mg concentration in the p-type layer 24 is 1×10¹⁸ cm⁻³ or more, the p-type layer 24 satisfies the following expression (1).

Y≥−5.5 log X+110 (1)

Here, X is Mg concentration in the p-type layer 24 expressed in cm⁻³. Y is the activation ratio of Mg in the p-type layer 24 expressed in percent.

In this manner, because Mg in the p-type layer 24 exhibits a high activation ratio, carrier concentration in the p-type layer 24 can be set over a wide range of 1×10¹⁵ cm⁻³ or more and 5×10¹⁸ cm⁻³ or less.

The thickness of the p-type layer 24 is, for example, 10 nm or more. This enables the p-type layer 24 to function as a p-type contact layer. Note that as the p-type layer 24 becomes thicker, productivity may decrease due to longer processing time required for activating the p-type impurity, and device characteristics may deteriorate due to an increase in series resistance. Therefore, it is preferable to set an upper limit of the thickness of the p-type layer 24 in view of these issues. The thickness of the p-type layer 24 can be, for example, 5 μm or less, and preferably 3 μm or less. The thickness of the p-type layer 24 to the above thickness, and therefore, a GaN vertical device having the p-type layer 24, as a semiconductor device produced using the semiconductor stack 1 can be made to function suitably.

### PN Junction Interface

In the PN junction structure 20, a PN junction is constituted by the n-type layer 22 and the p-type layer 24.

In this embodiment, when providing the PN junction structure 20, the n-type layer 22 and the p-type layer 24 are continuously grown using the same HVPE apparatus 200. Also, when the n-type layer 22 and the p-type layer 24 are continuously grown, using, for example, the HVPE apparatus 200 described later, generation of an Mg-containing gas is started before the start of growth of the p-type layer 24, and growth of the p-type layer 24 is started while keeping generation of the Mg-containing gas continued without stopping, as described later. Therefore, even in a case where the n-type layer 22 and the p-type layer 24 are continuously grown using the same HVPE apparatus 200, growth of the p-type layer 24 can be started with surfaces of SUS members, which can be contacted by the halogen-containing gas necessary for generation of the Mg-containing gas, being in a stabilized state. Consequently, incorporation of Fe originating from SUS into the interface between the n-type layer 22 and the p-type layer 24, i.e., the PN junction interface, is suppressed.

Specifically, Fe concentration at the PN junction interface measured by SIMS is 2×10¹⁵ cm⁻³ or less. Preferably, Fe concentration at the PN junction interface is less than the detection limit of SIMS. A current SIMS detection limit for Fe is 5×10¹⁴ cm⁻³.

In addition, in this embodiment, when providing the PN junction structure 20, the n-type layer 22 and the p-type layer 24 are continuously grown using the same HVPE apparatus 200. Therefore, incorporation at the PN junction interface of unintended impurities such as Si or O originating from impurities in ambient atmosphere is suppressed. Concentrations of unintended impurities at the PN junction interface are less than the detection limits of SIMS.

Specifically, C concentration, O concentration, B concentration, and Si concentration at the PN junction interface measured by SIMS are each less than the detection limit of SIMS. Current SIMS detection limits for C, O, B, and Si are 5×10¹⁵ cm⁻³, 5×10¹⁵ cm⁻³, 1×10¹⁵ cm⁻³, and 1×10¹⁵ cm⁻³, respectively.

Furthermore, at the PN junction interface of this embodiment, none of As, Cl, P, Na, Li, K, Sn, Ti, Mn, Cr, Mo, W, and Ni is detected. That is, concentrations of these elements at the PN junction interface are less than SIMS detection limits. Note that current SIMS detection limits for these elements at the PN junction interface are the same as those for these elements in the n-type layer 22.

Thus, Fe concentration at the PN junction interface is 2×10¹⁵ cm⁻³ or less, and preferably less than the detection limit of SIMS. Concentrations of impurities other than Fe at the PN junction interface are also less than SIMS detection limits. In other words, in addition to the crystals constituting the n-type layer 22 and the p-type layer 24 being of high purity, impurities at the PN junction interface are extremely few. Therefore, the PN junction structure 20 has extremely good crystal quality.

### (2) Method of Producing Semiconductor Stack

The following specifically describes a method of producing the semiconductor stack 1 according to this embodiment.

The method of producing the semiconductor stack 1 of this embodiment includes, for example, a preparation step S10, a crystal growth step S20, and an unloading step S30.

### S10: Preparation Step

First, a base substrate 10 is prepared, and an HVPE apparatus 200 that accommodates the base substrate 10 is prepared. The preparation step S10 of this embodiment includes, for example, an apparatus preparation step S12, a source placement step S13, a high-temperature bake step S14, and a substrate placement step S18. Note that, as described later, in some cases the high-temperature bake step S14 is replaced with a normal bake step S16.

### S12: Apparatus Preparation Step

The HVPE apparatus 200 described below is prepared.

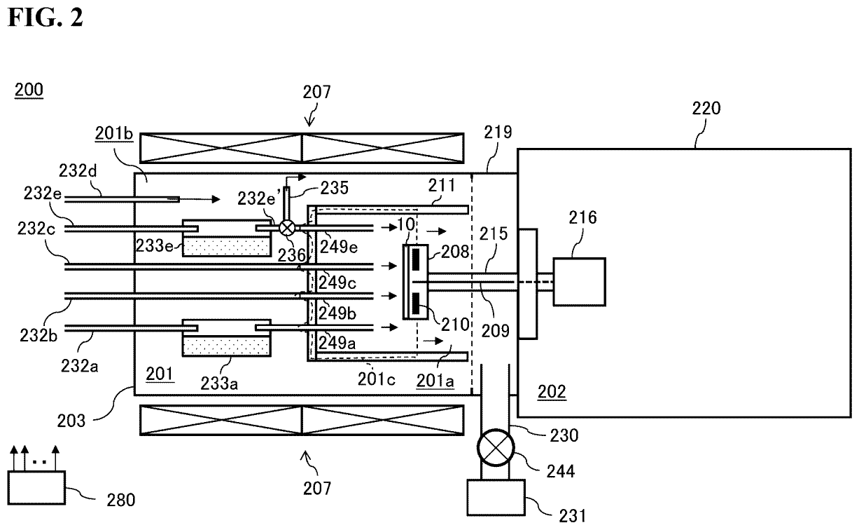

A configuration of the HVPE apparatus 200 used in growth of a GaN crystal will be described in detail with reference to FIG. 2. The HVPE apparatus 200 includes a reaction vessel 203 configured in, for example, a cylindrical shape. The reaction vessel 203 has a hermetic structure so that outside air and gas inside a glove box 220 described later do not enter the interior. Inside the reaction vessel 203, a reaction chamber 201 is formed. In the reaction chamber 201, a susceptor 208 that holds the base substrate 10 constituted from GaN single crystal is provided. The susceptor 208 is connected to a rotary shaft 215 of a rotation mechanism 216 and is configured to be rotatable. The susceptor 208 accommodates an internal heater 210. A temperature of the internal heater 210 is controllable separately from a zone heater 207 described later. Furthermore, an upstream side and a periphery of the susceptor 208 are covered by a heat shield wall 211. By providing the heat shield wall 211, gases other than gases supplied from nozzles 249a to 249c and 249e described later are prevented from being supplied to the base substrate 10. Also, by providing the heat shield wall 211, inside the reaction vessel 203, a first space 201a in which crystal growth is performed and a second space 201b that is different from (partitioned from) the first space 201a are formed. Specifically, the first space 201a is a space surrounded by the heat shield wall 211 (internal space of the heat shield wall 211), and the second space 201b is a space outside the heat shield wall 211 among spaces inside the reaction vessel 203.

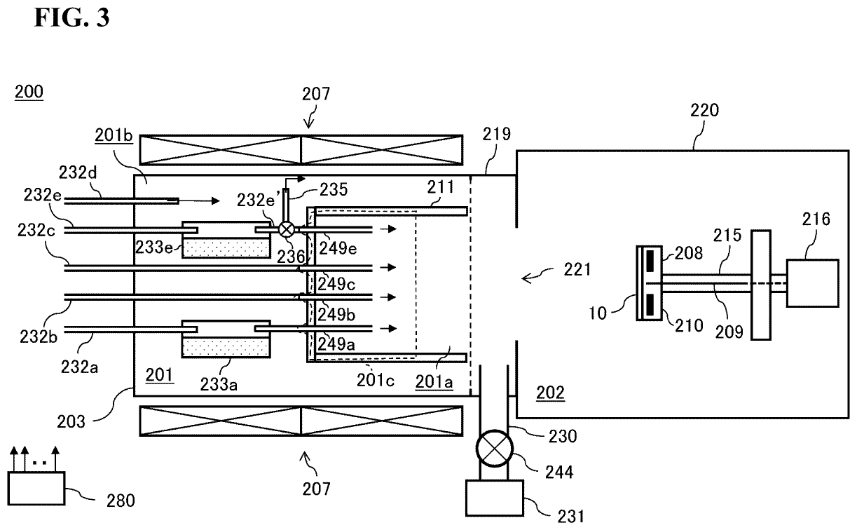

The reaction vessel 203 is connected to a glove box 220 via a metal flange 219 constituted from SUS or the like and formed in a cylindrical shape. The glove box 220 also has an airtight structure so that atmospheric air does not mix inside. An exchange chamber 202 provided inside the glove box 220 is continuously purged with high-purity nitrogen (hereinafter also simply referred to as N2 gas) and is maintained at low oxygen and moisture concentrations. The glove box 220 includes a transparent acrylic wall, a plurality of rubber gloves connected to holes penetrating the wall, and a pass box that transfers items between the inside and the outside of the glove box 220. The pass box is provided with a vacuum evacuation mechanism and an N2 purge mechanism, and is configured such that, by replacing atmospheric air inside the pass box with N2 gas, items can be transferred between the inside and the outside of the glove box 220 without drawing atmospheric air containing oxygen into the glove box 220. When loading or unloading a crystal substrate into or from the reaction vessel 203, as illustrated in FIG. 3, an opening of the metal flange 219, i.e., a furnace opening 221, is opened. This makes it possible to prevent surfaces of members inside the reaction vessel 203, for which cleaning and modification treatments have been completed by performing the high-temperature bake step S14 described later, from becoming contaminated again, and to prevent atmospheric air and gases containing the various impurities described above from adhering to the surfaces of these members.

At one end of the reaction vessel 203, a gas supply pipe 232a that supplies hydrogen chloride (HCl) gas into a gas generator 233a described later, a gas supply pipe 232b that supplies ammonia (NH₃) gas into the reaction chamber 201, a gas supply pipe 232c that supplies HCl gas for high-temperature bake and normal bake into the reaction chamber 201, a gas supply pipe 232d that supplies nitrogen (N₂) gas into the reaction chamber 201, and a gas supply pipe 232e that supplies a halogen-containing gas into a gas generator 233e described later are connected. The gas supply pipes 232a to 232c and 232e are also configured to be capable of supplying, in addition to HCl gas, NH₃ gas, and the halogen-containing gas, at least one of H₂ gas, N₂ gas, and a rare gas as a carrier gas. The gas supply pipe 232c is further configured to be capable of supplying, in addition to HCl gas, H₂ gas, and N2 gas, an n-type impurity-containing gas. The gas supply pipes 232a to 232e are each provided with a flow rate controller and a valve (both not illustrated) for each gas type, and are configured to allow flow-rate control and start/stop of supply of the various gases individually for each gas type.

N₂ gas supplied from the gas supply pipe 232d is used to purge the second space 201b (upstream side and periphery of the heat shield wall 211 in the reaction chamber 201) and to maintain cleanliness of the atmosphere in the second space 201b.

HCl gas supplied from the gas supply pipe 232c and H₂ gas supplied from the gas supply pipes 232a to 232c and 232e act, in the high-temperature bake step S14 and the normal bake step S16 described later, as cleaning gases that clean surfaces of members inside the reaction chamber 201 (particularly inside the first space 201a), and also act as modification gases that modify these surfaces into surfaces having a reduced probability of impurity release. N₂ gas supplied from the gas supply pipes 232a to 232c and 232e acts, in each bake step, to appropriately adjust ejection flow velocities of HCl gas and H₂ gas jetted from the tips of the nozzles 249a to 249c and 249e described later so that desired locations inside the reaction chamber 201 (particularly inside the first space 201a) are properly cleaned, for example.

HCl gas introduced from the gas supply pipe 232a acts, in a crystal growth step S20 described later, as a reaction gas that reacts with a Ga source to generate GaCl gas, which is a halide of Ga, i.e., a Ga source gas. NH3 gas supplied from the gas supply pipe 232b acts, in the crystal growth step S20 described later, as a nitriding agent, i.e., an N source gas, that reacts with GaCl gas to grow GaN, which is a nitride of Ga, on the base substrate 10. Hereinafter, GaCl gas and NH₃ gas may be collectively referred to as raw material gases. The halogen-containing gas introduced from the gas supply pipe 232e acts, in a p-type layer growth step S26 described later, as a gas that generates an Mg-containing gas by reacting with an Mg source and transports the Mg-containing gas to the base substrate 10 in the first space 201a. As the halogen-containing gas, a gas capable of generating an Mg-containing gas by reacting with the Mg source described later, for example HCl gas, HF gas, or CH₃F, can be used. Note that H₂ gas, N₂ gas, and rare gas supplied from the gas supply pipes 232a to 232c and 232e act, in the crystal growth step S20 described later, to appropriately adjust ejection flow velocities of the raw material gases, the n-type impurity-containing gas, and the Mg-containing gas jetted from the tips of the nozzles 249a to 249c and 249e described later, and to direct the raw material gases, the n-type impurity-containing gas, and the Mg-containing gas toward the base substrate 10.

Downstream of the gas supply pipe 232a, there is provided a gas generator 233a, as described above, that accommodates a Ga melt as a Ga source. The gas generator 233a is provided in the second space 201b. The gas generator 233a is provided with a nozzle 249a that supplies GaCl gas generated by reaction between HCl gas and the Ga melt toward a principal surface of the base substrate 10 held on the susceptor 208 in the first space 201a.

Downstream of the gas supply pipes 232b and 232c, nozzles 249b and 249c are provided that supply various gases supplied from these gas supply pipes toward the principal surface of the base substrate 10 held on the susceptor 208 in the first space 201a.

Downstream of the gas supply pipe 232e, there is provided a gas generator 233e, as described above, that accommodates MgF₂ or MgO as an Mg source (dopant source). The gas generator 233e is provided in the second space 201b. A gas supply pipe 232e′ that supplies an Mg-containing gas (dopant-containing gas) generated by reaction between the halogen-containing gas and the Mg source is connected to a downstream end of the gas generator 233e. At a downstream end of the gas supply pipe 232e′, a nozzle 249e is provided that supplies the Mg-containing gas generated in the gas generator 233e toward the principal surface of the base substrate 10 held on the susceptor 208 in the first space 201a.

The nozzles 249a to 249c and 249e are each configured to penetrate through the upstream side of the heat shield wall 211.

A vent pipe 235 is also connected to the gas supply pipe 232e′. Therefore, in the HVPE apparatus 200, as flow paths of the Mg-containing gas generated in the gas generator 233e, two flow paths are formed: a first flow path in which the Mg-containing gas is supplied to the base substrate 10 in the first space 201a through the gas supply pipe 232e′ and the nozzle 249e; and a second flow path in which the Mg-containing gas is discharged into the second space 201b through the gas supply pipe 232e′ and the vent pipe 235. A flow-path switching valve 236 that switches between the first flow path and the second flow path is provided at a site where the gas supply pipe 232e′ is connected with the vent pipe 235 (at a connection portion between the gas supply pipe 232e′ and the vent pipe 235).

The flow-path switching valve 236 is a valve specially designed based on recognition of the above new technical problem found by the inventors through intensive studies. The flow-path switching valve 236 can be placed in a harsh environment, for example inside the second space 201b that is heated to a high temperature of 700° C. or higher as described later, and is configured to be usable with high reliability even under such harsh conditions. The flow-path switching valve 236 has a simple structure. For example, the flow-path switching valve 236 is configured as a slide valve. Although it may be contemplated to use a commercially available solenoid valve as the flow-path switching valve 236, commercially available solenoid valves have complicated structures and are not suitable for use under the harsh conditions described above.

The metal flange 219 provided at the other end of the reaction vessel 203 is provided with an exhaust pipe 230 that evacuates the reaction chamber 201. An APC valve 244 as a pressure regulator and a pump 231 are provided in this order from the upstream side in the exhaust pipe 230. Note that, instead of the APC valve 244 and the pump 231, a blower including a pressure regulation mechanism may be used.

On an outer periphery of the reaction vessel 203, a zone heater 207 that heats the inside of the reaction chamber 201 to a desired temperature is provided. The zone heater 207 includes at least two heaters, i.e., a portion on the upstream side including the gas generator 233a and the gas generator 233e, and a portion on the downstream side including the susceptor 208. Each heater is provided with a temperature sensor and a temperature controller (both not illustrated) so that the heaters can individually adjust the temperature within a range from room temperature to 1200° C.

As described above, the susceptor 208 that holds the base substrate 10 is provided with, separately from the zone heater 207, an internal heater 210, a temperature sensor 209, and a temperature controller (not illustrated) so that the temperature can be adjusted within at least a range from room temperature to 1600° C. The upstream side and the periphery of the susceptor 208 are, as described above, surrounded by the heat shield wall 211. Among the surfaces of the heat shield wall 211, at least a surface (inner peripheral surface) facing the susceptor 208 needs to be constituted of limited members that do not generate impurities as described later, whereas for other surfaces (outer peripheral surface), there is no limitation on members to be used as long as the members can withstand temperatures of 1600° C. or higher. Portions of the heat shield wall 211 excluding at least the inner peripheral surface can be constituted of, for example, highly heat-resistant nonmetallic materials such as carbon or silicon carbide (SiC), or highly heat-resistant metallic materials such as Mo or W, and can have a structure in which plate-shaped reflectors are stacked. By employing such a configuration, even when a temperature of the susceptor 208 is set to 1600° C., a temperature outside the heat shield wall 211 (i.e., in the second space 201b) can be suppressed to 1200° C. or lower. Since this temperature is below the softening point of quartz, in the present configuration, quartz can be used as members constituting the reaction vessel 203 and the gas generator 233a.

The gas generator 233e, the gas supply pipe 232e′, and the flow-path switching valve 236 are provided in the second space 201b. As described above, the second space 201b may be heated to about 1200° C. Therefore, members constituting the gas generator 233e, the gas supply pipe 232e′, and the flow-path switching valve 236 need to be able to withstand a temperature of about 1200° C. In addition, the gas generator 233e, the gas supply pipe 232e′, and the flow-path switching valve 236 may be contacted by a high-temperature (700° C. or higher) Mg-containing gas. Therefore, members constituting the gas generator 233e, the gas supply pipe 232e′, and the flow-path switching valve 236 also need to be members that do not react with high-temperature Mg. As members constituting the gas generator 233e, the gas supply pipe 232e′, and the flow-path switching valve 236, alumina (Al₂O₃), SiC, graphite, pyrolytic graphite, and boron nitride can be used, for example. Note that, because Mg exhibits strong reactivity with quartz at 700° C. or higher, quartz is unsuitable as members constituting the gas generator 233e, the gas supply pipe 232e′, and the flow-path switching valve 236.

As described above, the HVPE apparatus 200 of this embodiment is configured to be capable of switching, via the flow-path switching valve 236, between the first flow path and the second flow path of the Mg-containing gas. That is, the HVPE apparatus 200 of this embodiment is configured to be capable of discharging the Mg-containing gas from inside the reaction vessel 203 via the second space 201b without passing through the first space 201a. Therefore, in this embodiment, as members constituting each of the gas supply pipe 232e and flow rate controllers and valves provided to the gas supply pipe 232e, a metallic material such as SUS can be used.

Also, as members constituting each of the gas supply pipes 232a to 232d, the flow rate controllers and valves provided to the gas supply pipes 232a to 232d, and the vent pipe 235, a metallic material such as SUS can be used.

The first space 201a has a high-temperature reaction region 201c that is heated to a crystal growth temperature (900° C. or higher) of a group III nitride in the crystal growth step S20 described later, and that is contacted by gases supplied to the base substrate 10.

In this embodiment, at least surfaces of members constituting the high-temperature reaction region 201c are constituted from, for example, materials that contain no quartz (SiO₂) and no B, and have heat resistance of 1600° C.

Specifically, for example, an inner wall upstream of the susceptor 208 among inner walls of the heat shield wall 211, portions of the nozzles 249a to 249c and 249e that penetrate inside the heat shield wall 211, portions on the outside of the heat shield wall 211 that are heated to 900° C. or higher in the crystal growth step S20, and a surface of the susceptor 208 are constituted of heat-resistant materials such as Al₂O₃, SiC, graphite, pyrolytic graphite, and boron nitride. Although not included in the high-temperature reaction region 201c, it goes without saying that heat resistance of at least 1600° C. is also required around the internal heater 210. Note that such high heat resistance is required for members constituting the high-temperature reaction region 201c and the like because, as described later, the high-temperature bake step S14 is performed before the crystal growth step S20.

The members provided in the HVPE apparatus 200, for example various valves and flow rate controllers provided to the gas supply pipes 232a to 232e, the pump 231, the APC valve 244, the zone heater 207, the internal heater 210, the temperature sensor 209, the flow-path switching valve 236, and the like, are connected to a controller 280 configured as a computer.

Next, an example of a process using the HVPE apparatus 200 described above will be described in detail with reference to FIG. 2. In the following description, operations of respective parts constituting the HVPE apparatus 200 are controlled by the controller 280.

### S13: Source Placement Step

After preparation of the HVPE apparatus 200 is completed, a Ga source is charged into the gas generator 233a placed in the second space 201b, and an Mg source is charged into the gas generator 233e.

### S14: High-Temperature Bake Step

This step is performed when the reaction chamber 201 and the exchange chamber 202 have been exposed to atmospheric air due to maintenance of the HVPE apparatus 200, execution of the source placement step S13, or the like. Before performing this step, it is confirmed that airtightness of the reaction chamber 201 and the exchange chamber 202 is ensured. After airtightness is confirmed, the insides of the reaction chamber 201 and the exchange chamber 202 are each replaced with N₂ gas to make these chambers into a state of low oxygen and moisture concentrations, and then surfaces of various members constituting the reaction chamber 201 are subjected to heat treatment while the inside of the reaction vessel 203 is in a predetermined atmosphere. This treatment is performed in a state where the base substrate 10 has not been loaded into the reaction vessel 203, and in a state where charging of the Ga source into the gas generator 233a and charging of the Mg source into the gas generator 233e have been performed.

In this step, the temperature of the zone heater 207 is adjusted to approximately the same temperature as in the crystal growth step S20 described later. Specifically, the temperature of the heater on the upstream side including the gas generators 233a and 233e is set to 700° C. to 900° C., and the temperature of the heater on the downstream side including the susceptor 208 is set to 1000° C. to 1200° C. Further, the temperature of the internal heater 210 is set to a predetermined temperature of 1500° C. or higher. As described later, in the crystal growth step S20, the internal heater 210 is turned off or set to a temperature of 1200° C. or lower, so the temperature of the high-temperature reaction region 201c becomes 900° C. or higher and less than 1200° C. By contrast, in the high-temperature bake step S14, by setting the temperature of the internal heater 210 to 1500° C. or higher, the temperature of the high-temperature reaction region 201c becomes 1000° C. to 1500° C. or higher; the vicinity of the susceptor 208 on which the base substrate 10 is placed reaches a high temperature of 1500° C. or higher, and at other locations as well, the temperature at each location becomes at least 100° C. higher than during execution of the crystal growth step S20. Among the high-temperature reaction region 201c, the portion that is 900° C.—i.e., the lowest temperature during the crystal growth step S20—specifically, the upstream portion of the nozzles 249a to 249c and 249e inside the heat shield wall 211, is the area where adhering impurity gas is most difficult to remove. By setting the temperature of the internal heater 210 to 1500° C. or higher so that the temperature of this portion becomes at least 1000° C., the effects of the cleaning and modification treatments described later—i.e., the effect of reducing impurities in the GaN crystal to be grown—can be sufficiently obtained. When the temperature of the internal heater 210 is set to less than 1500° C., it may not be possible to raise the temperature sufficiently at some point in the high-temperature reaction region 201c, making it difficult to obtain the effects of the cleaning and modification treatments described later, i.e., impurity reduction in the GaN crystal.

The upper limit of the temperature of the internal heater 210 in this step depends on the capability of the heat shield wall 211. That is, as long as the temperatures of quartz parts and the like outside the heat shield wall 211 can be kept below the heat-resistant temperatures thereof, the higher the temperature of the internal heater 210, the easier it is to obtain the effects of the cleaning and modification treatments described later. When the temperatures of quartz parts and the like outside the heat shield wall 211 exceed the heat-resistant temperatures thereof, the maintenance frequency and cost of the HVPE apparatus 200 may increase in some cases.

In this step, after the temperatures of the zone heater 207 and the internal heater 210 have reached the predetermined temperatures described above, H₂ gas is supplied from each of the gas supply pipes 232a, 232b, and 232e at a flow rate of, for example, about 3 slm. Note that supply of HCl gas from the gas supply pipe 232a and supply of a halogen-containing gas from the gas supply pipe 232e are not performed. In addition, from the gas supply pipe 232c, HCl gas is supplied at a flow rate of, for example, about 2 slm and H₂ gas is supplied at a flow rate of, for example, about 1 slm. Further, N₂ gas is supplied from the gas supply pipe 232d at a flow rate of, for example, about 10 slm. Then, by maintaining this state for a predetermined time, baking inside the reaction chamber 201 is performed. By starting supply of H₂ gas and HCl gas at the above timing, i.e., after the temperature inside the reaction chamber 201 has been raised, it is possible to reduce the amount of gas that would otherwise be wasted without contributing to the cleaning and modification treatments described later, thereby reducing the processing cost of crystal growth.

This step is performed while operating the pump 231; at that time, by adjusting the opening degree of the APC valve 244, the pressure inside the reaction vessel 203 is maintained, for example, at a pressure of 0.5 atm or more and 2 atm or less. Performing this step while evacuating the inside of the reaction vessel 203 makes it possible to efficiently remove impurities from inside the reaction vessel 203, i.e., to clean the inside of the reaction vessel 203. When the pressure inside the reaction vessel 203 is less than 0.5 atm, the effects of the cleaning and modification treatments described later become difficult to obtain. When the pressure inside the reaction vessel 203 exceeds 2 atm, etching damage to the members in the reaction chamber 201 becomes excessive.

In this step, a partial-pressure ratio of HCl gas to H2 gas inside the reaction vessel 203 (partial pressure of HCl/partial pressure of H₂) is set, for example, to a magnitude of 1/50 to ½. When the above partial-pressure ratio is smaller than 1/50, the effects of the cleaning and modification treatments described later become difficult to obtain. When the above partial-pressure ratio is larger than ½, etching damage to members in the reaction chamber 201 becomes excessive. This partial-pressure control can be carried out by adjusting the flow rates with the flow rate controllers provided to the gas supply pipes 232a to 232e.

By performing this step for, for example, 30 minutes or more and 300 minutes or less, surfaces of various members constituting at least the high-temperature reaction region 201c in the reaction chamber 201 can be cleaned, and foreign matter adhering to these surfaces can be removed. By then keeping the surfaces of these members at temperatures 100° C. or higher than the temperature in the crystal growth step S20 described later, it is possible to promote the release of impurity gases from these surfaces and to modify the surfaces into those from which release of impurities such as Si, B, Fe, O, and C hardly occurs under the temperature and pressure conditions of the crystal growth step S20. When the execution time of this step is less than 30 minutes, the effects of the cleaning and modification treatments described here may be insufficient. When the execution time of this step exceeds 300 minutes, damage to members constituting the high-temperature reaction region 201c becomes excessive.

When supplying H₂ gas and HCl gas into the reaction vessel 203, supply of NH₃ gas into the reaction vessel 203 is not performed. Supplying NH₃ gas into the reaction vessel 203 in this step makes it difficult to obtain the effects of the cleaning and modification treatments described above, particularly the effect of the modification treatment.

When supplying H₂ gas and HCl gas into the reaction vessel 203, a halogen-based gas such as chlorine (Cl₂) gas may be supplied instead of HCl gas. In this case as well, the effects of the cleaning and modification treatments described above can be similarly obtained.

When supplying H₂ gas and HCl gas into the reaction vessel 203, N₂ gas may be added as a carrier gas from the gas supply pipes 232a to 232c and 232e. By adjusting the ejection flow velocities of gases from the nozzles 249a to 249c and 249e through addition of N₂ gas, occurrence of portions where the cleaning and modification treatments described above are incomplete can be prevented. A rare gas such as Ar gas or He gas may be supplied instead of N₂ gas.

After completion of the cleaning and modification treatments described above, the output of the zone heater 207 is reduced, and the inside of the reaction vessel 203 is cooled to, for example, a temperature of 200° C. or lower—i.e., a temperature at which loading of the base substrate 10 into the reaction vessel 203 and the like becomes possible. Also, supply of H₂ gas and HCl gas into the reaction vessel 203 is stopped, and the inside of the reaction vessel 203 is purged with N₂ gas. After completion of purging inside the reaction vessel 203, while maintaining supply of N₂ gas into the reaction vessel 203, the opening degree of the APC valve 244 is adjusted so that the pressure inside the reaction vessel 203 becomes atmospheric pressure or a pressure slightly higher than atmospheric pressure.

### S16: Normal Bake Step

The high-temperature bake step S14 described above is performed when the inside of the reaction chamber 201 and the inside of the exchange chamber 202 have been exposed to the atmosphere. However, when performing the crystal growth step S20, neither the reaction chamber 201 nor the exchange chamber 202 typically is exposed to the atmosphere during, before, or after that step, and thus the high-temperature bake step S14 becomes unnecessary. Nevertheless, by performing the crystal growth step S20, polycrystalline GaN adheres to surfaces of the nozzles 249a to 249c and 249e, the surface of the susceptor 208, the inner wall of the heat shield wall 211, and the like. When the crystal growth step S20 is carried out next while polycrystalline GaN remains, Ga droplets or GaN polycrystalline powder separated and scattered from the polycrystal may adhere to the base substrate 10, thereby hindering good crystal growth. Therefore, after performing the crystal growth step S20, the normal bake step S16 is performed for the purpose of removing the polycrystalline GaN described above. The procedure and conditions of the normal bake step S16 can be similar to those of the high-temperature bake step S14 except that the internal heater 210 is turned off and the temperature near the susceptor 208 is set to 1000° C. to 1200° C. By performing the normal bake step S16, polycrystalline GaN can be removed from inside the reaction chamber 201.

### S18: Substrate Placement Step

After performing the high-temperature bake step S14 or the normal bake step S16, when cooling and purging inside the reaction vessel 203 are completed, the substrate placement step S18 is performed to accommodate the base substrate 10 in the reaction vessel 203.

As illustrated in FIG. 3, the furnace opening 221 of the reaction vessel 203 is opened, and the base substrate 10 is placed on the susceptor 208. The furnace opening 221 is isolated from the atmosphere and connected to the glove box 220 that is continuously purged with N2 gas. As described above, the glove box 220 includes a transparent acrylic wall, a plurality of rubber gloves connected to holes penetrating the wall, and a pass box that transfers items between the inside and the outside of the glove box 220. By replacing atmospheric air in the pass box with N2 gas, items can be transferred between the inside and the outside of the glove box 220 without drawing atmospheric air into the glove box 220. By performing the placement operation of the base substrate 10 using such a mechanism, it is possible to prevent re-contamination of each member inside the reaction vessel 203, which has completed cleaning and modification treatment by performing the high-temperature bake step S14, and to prevent re-adhesion of impurity gases to these members. The surface of the base substrate 10 placed on the susceptor 208—i.e., the principal surface on the side facing the nozzles 249a to 249c and 249e (crystal growth surface, base surface)—is (0001) plane of the GaN crystal, i.e., the +c plane (Ga-polar surface), for example.

### S20: Crystal Growth Step

After completion of accommodating the base substrate 10 into the reaction chamber 201, the following crystal growth step S20 is performed using the HVPE apparatus 200 to provide the PN junction structure 20 on the base substrate 10. The crystal growth step S20 includes, for example, an n-type layer growth step S22, an Mg-containing gas generation step S24, and a p-type layer growth step S26.

### S22: N-Type Layer Growth Step

In this step, a halide of a group III element, a nitriding agent, and an n-type impurity-containing gas are supplied to the base substrate 10 in the first space 201a, and an n-type layer 22 containing an n-type impurity is grown on the base substrate 10.

Specifically, after loading the base substrate 10 into the reaction chamber 201, the furnace opening 221 is closed, and while heating and evacuating the reaction chamber 201, supply of H₂ gas or supply of H₂ gas and N₂ gas into the reaction chamber 201 is started. When the interior of the reaction chamber 201 reaches a desired processing temperature and processing pressure and the atmosphere inside the reaction chamber 201 becomes a desired atmosphere, supplies of HCl gas, NH₃ gas, and an n-type impurity-containing gas from the gas supply pipes 232a, 232b, and 232c are started, and GaCl gas, NH₃ gas, and the n-type impurity-containing gas are supplied to the surface of the base substrate 10. As the n-type impurity-containing gas, for example, an Si-containing gas such as silane (SiH₄) gas or dichlorosilane (SiH₂Cl₂) gas, or a Ge-containing gas such as tetrachlorogermane (GeCl₄) gas can be used. In this embodiment, an example using SiH₂Cl₂ gas as the n-type impurity-containing gas is described. As a result, the n-type layer 22 constituted from single-crystal GaN containing an n-type impurity can be grown on the base substrate 10.

In this step, in order to prevent thermal decomposition of the GaN crystal constituting the base substrate 10, it is preferable to start supply of NH3 gas into the reaction chamber 201 at the time when the temperature of the base substrate 10 reaches 500° C. or before that. In addition, in order to improve in-plane thickness uniformity of the n-type layer 22 and the p-type layer 24, it is preferable to perform the crystal growth step S20 (at least the n-type layer growth step S22 and the p-type layer growth step S26 described later) while rotating the susceptor 208.

In this step, it is preferable that the temperature of the zone heater 207 be set to, for example, 700° C. to 900° C. on the upstream side including the gas generators 233a and 233e, and to, for example, 1000° C. to 1200° C. on the downstream side including the susceptor 208. This adjusts the temperature of the susceptor 208 to a predetermined crystal growth temperature of 1000° C. to 1200° C. In this step, the internal heater 210 may be used in the off state; however, temperature control using the internal heater 210 may be performed as long as the temperature of the susceptor 208 is within the range of 1000° C. to 1200° C. described above.

Other processing conditions in this step include the following examples.
Processing pressure: 0.5 atm to 2 atm
Partial pressure of GaCl gas: 0.1 kPa to 20 kPa
Partial pressure of NH₃ gas/partial pressure of GaCl gas: 1 to 100
Partial pressure of H₂ gas/partial pressure of GaCl gas: 0 to 100
Partial pressure of an n-type impurity-containing gas (SiH₂Cl₂ gas): 0.1 Pa to 10 Pa

After completion of growth of the n-type layer 22, supply of the n-type impurity-containing gas from the gas supply pipe 232c is stopped.

### S24: Mg-Containing Gas Generation Step

In this step, a halogen-containing gas is supplied to the Mg source in the second space 201b, and an Mg-containing gas is generated by reaction between the halogen-containing gas and the Mg source.

Specifically, first, it is confirmed that the flow path of the Mg-containing gas is the second flow path. When the flow path of the Mg-containing gas is not the second flow path, the flow-path switching valve 236 is controlled to switch the flow path of the Mg-containing gas to the second flow path. After confirming the flow path of the Mg-containing gas, supply of, for example, HCl gas as the halogen-containing gas from the gas supply pipe 232e is started. As a result, for example MgF₂ or MgO as the Mg source in the gas generator 233e reacts with HCl gas to generate an Mg-containing gas. The Mg-containing gas generated in the gas generator 233e is discharged to outside the reaction vessel 203 through the second flow path without passing through the first space 201a—i.e., through the gas supply pipe 232e′, the flow-path switching valve 236, the vent pipe 235, and the second space 201b.

This step is started before the start of the p-type layer growth step S26 described later. This step may be started at any timing as long as the timing is before the start of the p-type layer growth step S26. For example, this step may be started before execution (start) of the n-type layer growth step S22, simultaneously with the start of the n-type layer growth step S22, or during execution of the n-type layer growth step S22.

When the execution time of this step is less than 5 minutes, the surfaces of SUS members may not be sufficiently stabilized by the start of the p-type layer growth step S26. Therefore, it is preferable to perform this step for 5 minutes or longer, for example.

Thus, in this embodiment, the Mg-containing gas is generated from before the start of the p-type layer growth step S26. This allows the surfaces of SUS members to be stabilized by the time the p-type layer growth step S26 starts.

In addition, in this embodiment, the Mg-containing gas generated before the start of the p-type layer growth step S26 is discharged to outside the reaction vessel 203 through the second flow path without passing through the first space 201a. Therefore, even when this step is performed concurrently with the n-type layer growth step S22, incorporation of Mg and incorporation of Fe originating from SUS into the n-type layer 22 is suppressed.

### S26: P-Type Layer Growth Step

After completion of growth of the n-type layer 22, the HVPE apparatus 200 is continuously used, and a halide of a group III element, a nitriding agent, and an Mg-containing gas are supplied to the base substrate 10 in the first space 201a, thereby growing a p-type layer 24 containing Mg as a p-type impurity above the base substrate 10 (on the n-type layer 22).

Specifically, while continuing supplies of HCl gas, NH3 gas, and the halogen-containing gas from the gas supply pipes 232a, 232b, and 232e without stopping, the flow-path switching valve 236 is controlled to switch the flow path of the Mg-containing gas generated in the gas generator 233e from the second flow path to the first flow path. As a result, GaCl gas, NH₃ gas, and the Mg-containing gas are supplied to the surface of the base substrate 10 in the first space 201a, and a p-type layer 24 constituted from single-crystal GaN containing Mg as a p-type impurity can be grown above the base substrate 10 (on the n-type layer 22).

At this time, the partial pressure of the halogen-containing gas supplied from the gas supply pipe 232e is set, for example, to 1 Pa or more and 1 kPa or less. Processing conditions in the p-type layer growth step S26 other than the partial pressure of the halogen-containing gas are similar to those of the n-type layer growth step S22, except for the partial pressure of the n-type impurity-containing gas.

Thus, in this embodiment, supply of the halogen-containing gas from the gas supply pipe 232e is started before the start of this step, and this step is started by controlling the flow-path switching valve 236 to switch the flow path of the Mg-containing gas from the second flow path to the first flow path while keeping supply of the halogen-containing gas continued without stopping. Therefore, this step can be started with the surfaces of SUS members being in a stabilized state. This avoids high-concentration discharge of Fe originating from SUS particularly in an initial stage of growth of the p-type layer 24. As a result, even when the n-type layer growth step S22 and the p-type layer growth step S26 are carried out consecutively, incorporation of Fe into the interface between the n-type layer 22 and the p-type layer 24 (PN junction interface) is suppressed.

Moreover, the n-type layer growth step S22 and the p-type layer growth step S26 are continuously performed within the same HVPE apparatus 200 without exposing the base substrate 10 to the atmosphere. This suppresses formation at the PN junction interface of high-concentration regions of unintended impurities such as Si or O originating from impurities in ambient atmosphere (regions having Si or O concentrations relatively higher than in the n-type layer 22 and the p-type layer 24).

After completion of growth of the p-type layer 24, the flow-path switching valve 236 is controlled to switch the flow path of the Mg-containing gas from the first flow path to the second flow path.

### S30: Unloading Step

After the n-type layer 22 and the p-type layer 24 are grown in this order on the base substrate 10 to provide the PN junction structure 20, while supplying NH₃ gas and N₂ gas into the reaction chamber 201 and evacuating the reaction chamber 201, supplies of HCl gas, the halogen-containing gas, and H₂ gas into the reaction chamber 201 and heating by the zone heater 207 are stopped. When the temperature inside the reaction chamber 201 has cooled to 500° C. or lower, supply of NH₃ gas is stopped, the atmosphere in the reaction chamber 201 is replaced with N₂ gas, and the pressure inside the reaction chamber 201 is returned to atmospheric pressure. The inside of the reaction chamber 201 is then cooled to, for example, a temperature of 200° C. or lower—i.e., a temperature at which the semiconductor stack 1 can be unloaded from inside the reaction vessel 203. Thereafter, the semiconductor stack 1 is unloaded from the reaction chamber 201 via the glove box 220 and the pass box.

In this manner, the semiconductor stack 1 of this embodiment is produced.

When manufacturing a plurality (n) of semiconductor stacks 1, it is preferable to perform the sequence in the order of: exposing the inside of the reaction chamber 201 and the inside of the exchange chamber 202 to the atmosphere→high-temperature bake step S14→crystal growth step S20→unloading step S30→(normal bake step S16→crystal growth step S20→unloading step S30)×(n−1).

### 3Effects

According to this embodiment, one or more of the effects shown below are obtained.
(a) In the PN junction structure 20 of this embodiment, both suppression of incorporation of Mg in the n-type layer 22 and reduction of Fe concentration at the PN junction interface are achieved. Specifically, in the PN junction structure 20 of this embodiment, Mg concentration in the n-type layer is less than 1×10¹⁶ cm⁻³, and Fe concentration at the interface of the PN junction is 2×10¹⁵ cm⁻³ or less. Thus, according to this embodiment, a high-quality semiconductor stack 1 having the PN junction structure 20 including the n-type layer 22 and the p-type layer 24 is obtained. Therefore, it becomes possible to improve characteristics and extend the lifetime of a semiconductor device such as a PN junction diode produced from the semiconductor stack 1.
(b) In the HVPE apparatus 200 of this embodiment, as flow paths of the Mg-containing gas generated in the gas generator 233e, two flow paths are configured: a first flow path in which the Mg-containing gas is supplied to the base substrate 10 in the first space 201a via the gas supply pipe 232e′ and the nozzle 249e; and a second flow path in which the Mg-containing gas is discharged into the second space 201b via the gas supply pipe 232e′ and the vent pipe 235. Switching between the first flow path and the second flow path is performed via the flow-path switching valve 236.

Accordingly, in the HVPE apparatus 200, it is possible to start generation of the Mg-containing gas before the start of growth of the p-type layer 24 and to discharge the Mg-containing gas generated before the start of growth of the p-type layer 24 outside the reaction vessel 203 through the second flow path without passing through the first space 201a. Therefore, even when the Mg-containing gas is generated while the n-type layer 22 is being grown (even when the n-type layer growth step S22 and the Mg-containing gas generation step S24 are carried out concurrently), incorporation of Mg into the n-type layer 22 is suppressed.

Further, generation of the Mg-containing gas is started before the start of growth of the p-type layer 24, and the flow-path switching valve 236 is controlled to switch the flow path of the Mg-containing gas from the second flow path to the first flow path, to start growth of the p-type layer 24. Therefore, growth of the p-type layer 24 can be started with the surfaces of SUS members being in a stabilized state. This avoids high-concentration discharge of Fe originating from SUS in the initial stage of growth of the p-type layer 24. As a result, incorporation of Fe into the PN junction interface is suppressed.

Consequently, even when the n-type layer 22 and the p-type layer 24 are continuously grown using the same HVPE apparatus 200, both suppression of incorporation of Mg in the n-type layer 22 and reduction of Fe concentration at the PN junction interface can be achieved.
(c) By discharging the Mg-containing gas generated before the start of growth of the p-type layer 24 outside the reaction vessel 203 through the second flow path without passing through the first space 201a, even when the Mg-containing gas is generated while the n-type layer 22 is being grown, incorporation of Fe originating from SUS into the n-type layer 22 is suppressed. Therefore, Fe concentration in the n-type layer 22 of this embodiment is 2×10¹⁵ cm⁻³ or less.
(d) In this embodiment, the n-type layer 22 and the p-type layer 24 are continuously grown by the HVPE method to provide the PN junction structure 20. Therefore, incorporation of C into the n-type layer 22 and the p-type layer 24 is suppressed. In contrast, when the n-type layer 22 and the p-type layer 24 are grown by the MOCVD method, unintended impurity C is incorporated at a high concentration into the n-type layer 22 and the p-type layer 24 due to various organic source gases used for crystal growth.

Moreover, as described above, in this embodiment, the n-type layer 22 and the p-type layer 24 are grown inside the high-temperature reaction region 201c that has undergone cleaning and modification treatments, while suppressing release of impurities such as C, Si, B, and O from the high-temperature reaction region 201c. This suppresses incorporation of these unintended impurities into the n-type layer 22 and the p-type layer 24.

As a result, concentrations of C, Si, B, and O in the n-type layer 22 and the p-type layer 24 obtained in this embodiment are less than the detection limits. Thus, the crystals constituting the n-type layer 22 and the p-type layer 24 obtained in this embodiment are of high purity. Therefore, compared to crystals containing more of these impurities, the n-type layer 22 and the p-type layer 24 have extremely good crystal quality with greatly reduced defect density, dislocation density, and internal stress. Consequently, characteristics of semiconductor devices obtained from the semiconductor stack 1 can be further improved.
(e) By using, for example, MgF₂ as the Mg source, a predetermined amount of Mg and a trace amount of F can be incorporated into the p-type layer 24. This improves the activation ratio of Mg in the p-type layer 24.

### (4) Modifications

This embodiment can be modified as described in the following modifications. In the descriptions of the following modifications, elements identical to those of the embodiments described above are denoted by the same reference numerals and the descriptions thereof are omitted. The embodiments described above and the following modifications can be combined arbitrarily.

### Modification 1

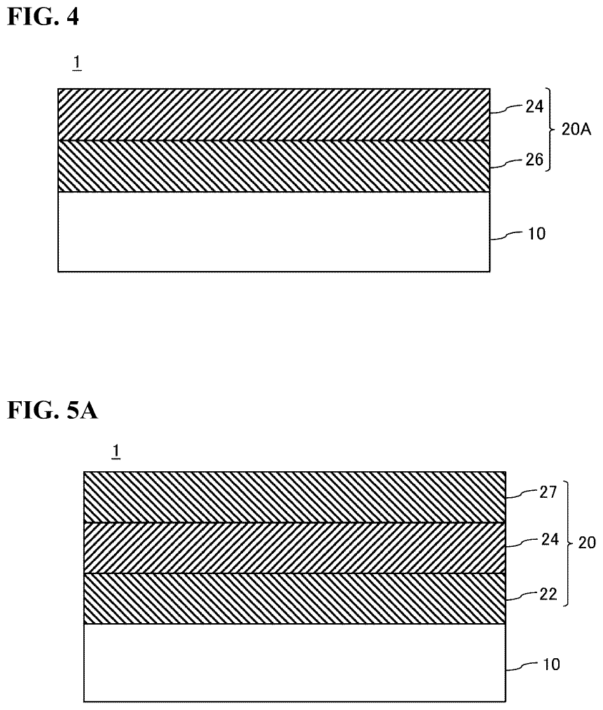

In the embodiments described above, the example in which the semiconductor stack 1 includes the base substrate 10 and the PN junction structure 20 was described, but the invention is not limited thereto. For example, as illustrated in FIG. 4, the semiconductor stack 1 may include the base substrate 10 and a PI junction structure 20A.

### PI Junction Structure

The PI junction structure 20A includes a semiconductor layer 26 (hereinafter, i-type layer 26) constituted from a group III nitride, and the p-type layer 24 constituted from a group III nitride containing Mg as a p-type impurity. In the PI junction structure 20A, a PI junction is constituted by the i-type layer 26 and the p-type layer 24. The configuration of the p-type layer 24 is the same as in the embodiments described above, and description in this modification is omitted.

### i-Type Semiconductor Layer

The i-type layer 26 is a layer having non-conductivity (insulating property). Here, “non-conductivity” means having lower conductivity than the p-type layer 24. For example, when the carrier concentration of the p-type layer 24 is 1×10¹⁰ cm⁻³ or higher, the carrier concentration of the i-type layer 26 is, for example, less than 1×10¹⁰ cm⁻³. Preferably, the i-type layer 26 is constituted from a group III nitride crystal to which neither an n-type impurity nor a p-type impurity is intentionally added. The i-type layer 26 is constituted, for example, from non-doped single-crystal GaN. The i-type layer 26 is provided on the base substrate 10 by epitaxially growing, for example, a group III nitride crystal by the HVPE method.

In this modification as well, when providing the PI junction structure 20A, using, for example, the HVPE apparatus 200 described above, generation of the Mg-containing gas is started before the start of growth of the p-type layer 24 (for example, while the i-type layer 26 is being grown or before the start of growth of the i-type layer 26), and the Mg-containing gas generated before the start of growth of the p-type layer 24 is discharged to outside the reaction vessel 203 without passing through the first space 201a. Therefore, even when the Mg-containing gas is generated while the i-type layer 26 is being grown, incorporation of Mg into the i-type layer 26 is suppressed.

Specifically, Mg concentration in the i-type layer 26 measured by SIMS is less than ×10¹⁶ cm⁻³. This ensures that the i-type layer 26 reliably has non-conductivity. Preferably, Mg concentration in the i-type layer 26 is less than the detection limit of SIMS. A current SIMS detection limit for Mg is 5×10¹⁴ cm⁻³. This more reliably ensures non-conductivity of the i-type layer 26.

In addition, by discharging the Mg-containing gas generated before the start of growth of the p-type layer 24 to outside the reaction vessel 203 without passing through the first space 201a, even when the Mg-containing gas is generated while the i-type layer 26 is being grown, incorporation of Fe originating from SUS members into the i-type layer 26 is also suppressed.

Specifically, Fe concentration in the i-type layer 26 measured by SIMS is, for example, 2×10¹⁵ cm⁻³ or less. Preferably, Fe concentration in the i-type layer 26 is less than the detection limit of SIMS. A current SIMS detection limit for Fe is less than 5×10¹⁴ cm⁻³. Further, Fe concentration in the i-type layer 26 measured by the ICTS method is, for example, 1×10¹³ cm⁻³ or less, and preferably 3×10¹² cm⁻³ or less.

In this modification as well, the i-type layer 26 is grown by the HVPE method. Therefore, compared with the case where the i-type layer 26 is grown by the MOCVD method, incorporation of C into the i-type layer 26 is suppressed. Also, unlike the case where the i-type layer 26 is grown by the flux method, the i-type layer 26 substantially contains no alkali metal elements such as Na and Li.

Further, in this modification as well, when growing the i-type layer 26 by the HVPE method, using, for example, the HVPE apparatus 200 described above, the growth is carried out inside the high-temperature reaction region 201c that has undergone cleaning and modification treatments while suppressing the release of impurities such as C, Si, B, and O from the high-temperature reaction region 201c. Therefore, incorporation of unintended impurities other than Mg and Fe into the i-type layer 26 is also suppressed.

Specifically, concentrations of Si, C, O, and B in the i-type layer 26 are each less than the detection limit of SIMS. Current SIMS detection limits for Si, C, O, and B are 1×10¹⁵ cm⁻³, 5×10¹⁵ cm⁻³, 5×10¹⁵ cm⁻³, and 1×10¹⁵ cm⁻³, respectively.

Furthermore, in the i-type layer 26 of this modification, none of As, Cl, P, F, Na, Li, K, Sn, Ti, Mn, Cr, Mo, W, and Ni is detected. That is, concentrations of these elements in the i-type layer 26 are less than SIMS detection limits. Note that current SIMS detection limits for these elements are the same as those in the n-type layer 22.

Thus, concentrations of unintended impurities in the i-type layer 26 are less than detection limits of SIMS. In other words, the crystal constituting the i-type layer 26 is of high purity.

The thickness of the i-type layer 26 is not particularly limited, but is, for example, similar to that of the n-type layer 22. That is, the thickness of the i-type layer 26 is, for example, 5 μm or more and 200 μm or less.

### PI Junction Interface

In the PI junction structure 20A, a PI junction is constituted by the i-type layer 26 and the p-type layer 24.

In this modification as well, when providing the PI junction structure 20A, using, for example, the HVPE apparatus 200 described above, generation of the Mg-containing gas is started before the start of growth of the p-type layer 24, and growth of the p-type layer 24 is started while keeping generation of the Mg-containing gas continued without stopping. Therefore, even in a case where the i-type layer 26 and the p-type layer 24 are continuously grown using the same HVPE apparatus 200, growth of the p-type layer 24 can be started with the surfaces of SUS members being in a stabilized state. As a result, incorporation of Fe originating from SUS into the interface between the i-type layer 26 and the p-type layer 24, i.e., the PI junction interface, is suppressed.

Specifically, Fe concentration at the PI junction interface measured by SIMS is 2×10¹⁵ cm⁻³ or less. Preferably, Fe concentration at the PI junction interface is less than the detection limit of SIMS. A current SIMS detection limit for Fe is 5×10¹⁴ cm⁻³.

In this modification as well, when providing the PI junction structure 20A, the i-type layer 26 and the p-type layer 24 are continuously grown using the same HVPE apparatus 200. Therefore, incorporation at the PI junction interface of unintended impurities such as Si or O originating from impurities in ambient atmosphere is suppressed. Concentrations of unintended impurities at the PI junction interface are less than the detection limits of SIMS.

Specifically, concentrations of C, O, B, and Si at the PI junction interface measured by SIMS are each less than the detection limit of SIMS. Current SIMS detection limits for C, O, B, and Si are 5×10¹⁵ cm⁻³, 5×10¹⁵ cm⁻³, 1×10¹⁵ cm⁻³, and 1×10¹⁵ cm⁻³, respectively.

Furthermore, at the PI junction interface of this modification, none of As, Cl, P, Na, Li, K, Sn, Ti, Mn, Cr, Mo, W, and Ni is detected. That is, concentrations of these elements at the PI junction interface are less than SIMS detection limits. Note that current SIMS detection limits for the elements at the PI junction interface are the same as those in the n-type layer 22.

In the method of manufacturing the semiconductor stack 1 in this modification, the crystal growth step S20 includes an i-type layer growth step S28, the Mg-containing gas generation step S24, and the p-type layer growth step S26. The procedure and conditions of the i-type layer growth step S28 can be similar to those of the n-type layer growth step S22 described above, for example, except that supply of the n-type impurity-containing gas from the gas supply pipe 232c is not performed.

In this modification as well, when providing the PI junction structure 20A, using, for example, the HVPE apparatus 200 described above, generation of the Mg-containing gas is started before the start of growth of the p-type layer 24, and the Mg-containing gas generated before the start of growth of the p-type layer 24 is discharged to outside the reaction vessel 203 without passing through the first space 201a. This avoids high-concentration discharge of Fe originating from SUS in an initial stage of growth of the p-type layer 24. As a result, incorporation of Fe into the PI junction interface is suppressed. Also, even when the Mg-containing gas is generated while the i-type layer 26 is being grown (even when the i-type layer growth step S28 described above and the Mg-containing gas generation step S24 described above are carried out concurrently), incorporation of Mg into the i-type layer 26 is suppressed. Consequently, in this modification as well, even when the i-type layer 26 and the p-type layer 24 containing Mg are continuously grown using the same HVPE apparatus 200, both suppression of incorporation of Mg in the i-type layer 26 and reduction of Fe concentration at the PI junction interface can be achieved.

Moreover, by discharging the Mg-containing gas generated before the start of growth of the p-type layer 24 to outside the reaction vessel 203 without passing through the first space 201a, even when the Mg-containing gas is generated while the i-type layer 26 is being grown, incorporation of Fe originating from SUS members into the i-type layer 26 is also suppressed.

From the above, in this modification as well, effects similar to those of the embodiments described above are obtained.

### Modification 2

In the embodiments and modification described above, the example in which MgF₂ or MgO is used as the Mg source and an Mg-containing gas is generated by reaction between the halogen-containing gas and the Mg source was described, but the invention is not limited thereto. Metallic Mg or Mg₃N₂ may be used as the Mg source, and an Mg-containing gas may be generated by vaporizing the Mg source.

In this modification as well, by using, for example, the HVPE apparatus 200 described above, the n-type layer 22 or i-type layer 26, and the p-type layer 24 can be continuously grown by the HVPE method. In this modification as well, as in the embodiments and the above modification, in the crystal growth step S20, the n-type layer growth step S22 or i-type layer growth step S28, the Mg-containing gas generation step S24, and the p-type layer growth step S26 are performed. The procedures and conditions of the n-type layer growth step S22, the p-type layer growth step S26, and the i-type layer growth step S28 are the same as those in the embodiments and modification described above, and description in this modification is omitted.

### S24: Mg-Containing Gas Generation Step

When metallic Mg or Mg₃N₂ is used as the Mg source as in this modification, at the time when the temperature in the second space 201b reaches a predetermined temperature, the Mg source in the gas generator 233e vaporizes, an Mg-containing gas is generated, and the Mg-containing gas generation step S24 starts. Therefore, in this modification, before the temperature in the second space 201b reaches the predetermined temperature—preferably before the start of temperature rise inside the reaction chamber 201 (before the start of the crystal growth step S20)—it is confirmed that the flow path of the Mg-containing gas is the second flow path.

Usually, when the temperature in the second space 201b reaches about 600° C., vaporization of the Mg source begins. This temperature is lower than the growth temperature (desired processing temperature described above) of the group III nitride crystal (GaN). Therefore, in this modification as well, the Mg-containing gas is generated before the start of growth of the p-type layer 24 (for example, before the start of growth of the n-type layer 22 or the i-type layer 26). In this modification as well, the Mg-containing gas generated before the start of growth of the p-type layer 24 is discharged to outside the reaction vessel 203 through the second flow path without passing through the first space 201a. At this time, H2 gas or a rare gas may be supplied as a carrier gas from the gas supply pipe 232e. Note that Mg reacts with nitrogen to form Mg₃N₂; therefore, N₂ gas is unsuitable as a carrier gas supplied from the gas supply pipe 232e.

Thus, in this modification as well, generation of the Mg-containing gas is started before the start of growth of the p-type layer 24, and the Mg-containing gas generated before the start of growth of the p-type layer 24 is discharged to outside the reaction vessel 203 without passing through the first space 201a. Therefore, even when the Mg-containing gas is generated while the n-type layer 22 or the i-type layer 26 is being grown, incorporation of Mg into the n-type layer 22 or the i-type layer 26 is suppressed.

Furthermore, in this modification, the Mg-containing gas can be generated without using a halogen-containing gas (i.e., without supplying a halogen-containing gas from the gas supply pipe 232e). Therefore, in this modification, Fe originating from SUS is hardly discharged. Accordingly, incorporation of Fe into the PN junction interface or the PI junction interface is suppressed. Incorporation of Fe originating from SUS into the n-type layer 22 or the i-type layer 26 is also suppressed.

Thus, in this modification as well, both suppression of incorporation of Mg in the n-type layer 22 or the i-type layer 26 and reduction of Fe concentration at the PN junction interface or the PI junction interface can be achieved.

In this modification as well, the n-type layer 22, the p-type layer 24, and the i-type layer 26 are provided by the HVPE method. Therefore, as compared with the case where these layers are grown by the MOCVD method, incorporation of C into the n-type layer 22, the p-type layer 24, and the i-type layer 26 is suppressed. In this modification as well, by using the HVPE apparatus 200 described above and growing the n-type layer 22, the p-type layer 24, and the i-type layer 26 inside the high-temperature reaction region 201c that has undergone cleaning and modification treatments while suppressing the release of impurities such as C, Si, B, and O from the high-temperature reaction region 201c, incorporation of these unintended impurities into these layers is suppressed. As a result, concentrations of C, Si, B, and O in the n-type layer 22, the p-type layer 24, and the i-type layer 26 obtained in this modification are less than the detection limits of SIMS.

From the above, in this modification as well, effects similar to those of the embodiments and modification described above are obtained.

### Modification 3

In the embodiments and modifications described above, the example in which the PN junction structure 20 includes the n-type layer 22 provided on the base substrate 10 and the p-type layer 24 provided on the n-type layer 22, and the example in which the PI junction structure 20A includes the i-type layer 26 provided on the base substrate 10 and the p-type layer 24 provided on the i-type layer 26 were described, but the invention is not limited thereto.

For example, the PN junction structure 20 may include the p-type layer 24 provided on the base substrate 10 and the n-type layer 22 provided on the p-type layer 24. Also, the PI junction structure 20A may include the p-type layer 24 provided on the base substrate 10 and the i-type layer 26 provided on the p-type layer 24.

In the crystal growth step S20 of this modification, it suffices to perform the Mg-containing gas generation step S24, the p-type layer growth step S26, and the n-type layer growth step S22 or i-type layer growth step S28 in this order. The procedures and conditions of each step can be the same as those of the n-type layer growth step S22, the Mg-containing gas generation step S24, the p-type layer growth step S26, and the i-type layer growth step S28 in the embodiments and modifications described above.

In this modification as well, when providing the PN junction structure 20 or the PI junction structure 20A, using, for example, the HVPE apparatus 200 described above, generation of the Mg-containing gas is started before the start of growth of the p-type layer 24, and the Mg-containing gas generated before the start of growth of the p-type layer 24 is discharged to outside the reaction vessel 203 through the second flow path without passing through the first space 201a. Therefore, regardless of whether MgF₂, MgO, metallic Mg, or Mg₃N₂ is used as the Mg source and even when the Mg-containing gas is generated while the n-type layer 22 or the i-type layer 26 is being grown, incorporation of Mg into the n-type layer 22 or the i-type layer 26 is suppressed.

In this modification as well, generation of an Mg-containing gas is started before the start of growth of the p-type layer 24, and growth of the p-type layer 24 is started by controlling the flow-path switching valve 236 to switch the flow path of the Mg-containing gas from the second flow path to the first flow path while keeping generation of the Mg-containing gas continued without stopping. Therefore, incorporation of Fe originating from SUS into the p-type layer 24 is suppressed. As a result, incorporation of Fe into the PN junction interface or the PI junction interface is suppressed.

Thus, in this modification as well, regardless of whether MgF₂, MgO, metallic Mg, or Mg₃N₂ is used as the Mg source, both suppression of incorporation of Mg in the n-type layer 22 or the i-type layer 26 and reduction of Fe concentration at the PN junction interface or the PI junction interface can be achieved. Therefore, in this modification as well, effects similar to those of the embodiments and modifications described above are obtained.

In this modification, by starting growth of the p-type layer 24 with the surfaces of SUS members being in a stabilized state as described above, incorporation of Fe originating from SUS into the interface between the base substrate 10 and the p-type layer 24 is also suppressed. This reliably improves characteristics of semiconductor devices obtained from the semiconductor stack 1.

### Modification 4

In the embodiments and modifications described above, the example in which the PN junction structure 20 includes one n-type layer 22 and one p-type layer 24 was described, but the invention is not limited thereto. That is, the PN junction structure 20 may include a plurality of n-type layers 22 and a plurality of p-type layers 24, and may be configured such that the n-type layers 22 and the p-type layers 24 are alternately stacked.

In this modification as well, when providing the PN junction structure 20, using, for example, the HVPE apparatus 200 described above, generation of the Mg-containing gas is started before the start of growth of each of the plurality of p-type layers 24, and the Mg-containing gas generated before the start of growth of the p-type layers 24 is discharged to outside the reaction vessel 203 without passing through the first space 201a. This avoids high-concentration discharge of Fe originating from SUS in an initial stage of growth of each of the plurality of p-type layers 24. As a result, incorporation of Fe into each PN junction interface is suppressed. Also, even when the Mg-containing gas is generated while the n-type layers 22 are being grown, incorporation of Mg into the n-type layers 22 is suppressed. Consequently, in this modification as well, both suppression of incorporation of Mg in each of the plurality of n-type layers 22 and reduction of Fe concentration at each of the plurality of PN junction interfaces can be achieved. In this modification as well, effects similar to those of the embodiments and modifications described above are obtained.

### Modification 5

In the embodiments and modifications described above, the example in which the semiconductor stack 1 is configured as a stack for producing a PN junction diode was described, but the invention is not limited thereto. For example, the semiconductor stack 1 may be configured as a stack for producing a vertical field-effect transistor (FET) having a trench gate structure (NPN structure, PNP structure, PIN structure).

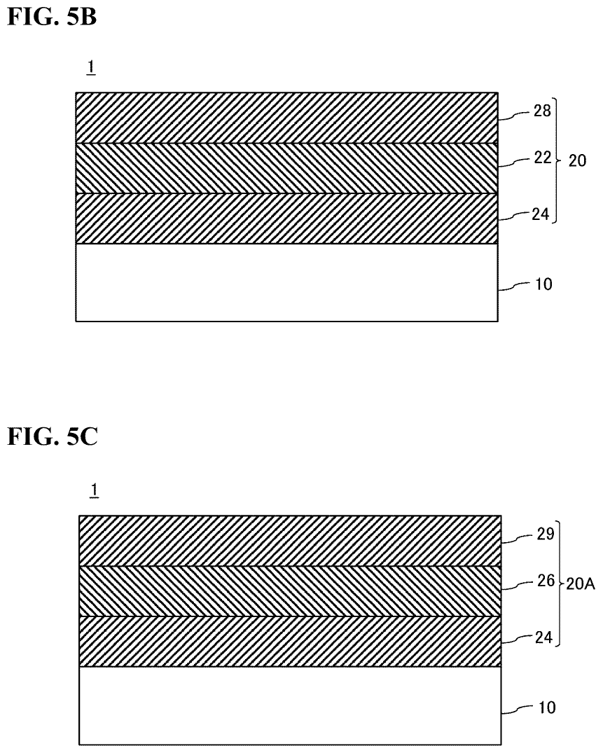

Specifically, as illustrated in, for example, FIG. 5A, the PN junction structure 20 may be an NPN structure including the n-type layer 22 on the base substrate 10, the p-type layer 24 on the n-type layer 22, and an n-type layer 27 on the p-type layer 24. The n-type layer 27 has, for example, the same configuration as the n-type layer 22 described above.

As illustrated in, for example, FIG. 5B, the PN junction structure 20 may be a PNP structure including the p-type layer 24 on the base substrate 10, the n-type layer 22 on the p-type layer 24, and a p-type layer 28 on the n-type layer 22. The p-type layer 28 has, for example, the same configuration as the p-type layer 24 described above.

As illustrated in, for example, FIG. 5C, the PI junction structure 20A may be a PIN structure including the p-type layer 24 on the base substrate 10, the i-type layer 26 on the p-type layer 24, and an n-type layer 29 on the i-type layer 26. The n-type layer 29 has, for example, the same configuration as the n-type layer 22 described above.

In this modification as well, using the HVPE apparatus 200 described above, generation of the Mg-containing gas is started before the start of growth of the p-type layer 24, and the Mg-containing gas generated before the start of growth of the p-type layer 24 is discharged to outside the reaction vessel 203 without passing through the first space 201a. Therefore, even when the Mg-containing gas is generated while the n-type layer 22 or the i-type layer 26 is being grown, incorporation of Mg into the n-type layer 22 or the i-type layer 26 is suppressed. In this modification as well, growth of the p-type layer 24 can be started with the surfaces of SUS members being in a stabilized state. Consequently, in this modification, even when the n-type layer 22 or i-type layer 26, and the p-type layer 24 are continuously grown using the same HVPE apparatus 200, both suppression of incorporation of Mg in the n-type layer 22 or the i-type layer 26 and reduction of Fe concentration at the PN junction interface or the PI junction interface can be achieved. Therefore, in this modification as well, effects similar to those of the embodiments and modifications described above are obtained.

### Other Embodiments

Embodiments of the present disclosure has been specifically described above. However, the present disclosure is not limited to the above embodiments and can be variously modified without departing from the gist thereof. The embodiments can be combined arbitrarily.

In the embodiments described above, the example in which the base substrate 10 is a GaN free-standing substrate was described, but the invention is not limited thereto. The base substrate 10 may be, for example, a silicon carbide (SiC) substrate, a Si substrate, or a sapphire (Al₂O₃) substrate.

In the embodiments described above, the example in which each of the semiconductor layers of the n-type layer 22, the p-type layer 24, and the i-type layer 26 is constituted from single-crystal GaN was described, but the invention is not limited thereto. Each semiconductor layer may be constituted not only from single-crystal GaN but also from a group III nitride crystal such as aluminum nitride (AlN), aluminum gallium nitride (AlGaN), indium nitride (InN), indium gallium nitride (InGaN), or aluminum indium gallium nitride (AlInGaN), i.e., a single crystal represented by the compositional formula InₓAl_{y}Ga_{1-x-y}N (where 0≤x≤1, 0≤y≤1, 0≤x+y≤1).

In the embodiments and modifications described above, the n-type layer 22 and the p-type layer 24 may be in either an activated state or an inactive state of the n-type impurity or the p-type impurity, respectively. That is, immediately after growth of the n-type layer 22, the n-type impurity is inactive, and immediately after growth of the p-type layer 24, the p-type impurity is inactive. To activate the n-type impurity and the p-type impurity, a predetermined heat treatment (hereinafter, activation heat treatment) needs to be performed on the n-type layer 22 and the p-type layer 24. The n-type layer 22 and the p-type layer 24 in the embodiments and modifications described above may be before or after execution of the activation heat treatment.

The activation heat treatment may be performed on the semiconductor stack 1 in which the PN junction structure 20 or the PI junction structure 20A is provided on the base substrate 10, or may be performed midway through a process of producing a semiconductor device from the semiconductor stack 1.

Examples of heat-treatment conditions when performing the activation heat treatment include the following.
Heating temperature: 400° C. to 900° C., preferably 700° C. to 800° C.
Heating time: 5 minutes to 60 minutes
Atmosphere: an atmosphere of a hydrogen-free gas, preferably N₂ gas or air

In the embodiments and modifications described above, as semiconductor devices produced from the semiconductor stack 1, a vertical PN junction diode and a vertical trench-gate FET were exemplified, but the invention is not limited thereto. The semiconductor stack 1 may be used to produce other semiconductor devices. For example, the semiconductor stack 1 may be configured to produce a lateral device. That is, a semiconductor stack 1 for manufacturing a lateral power device may be manufactured by growing the n-type layer 22 and the p-type layer 24, then ion-implanting an n-type impurity such as Si into the p-type layer 24.

### Preferred Embodiments of the Present Disclosure

Preferred embodiments of the present disclosure are Supplementary descriptions below.

(Supplementary description 1) A semiconductor stack including:
a base substrate; and
a PN junction structure including an n-type semiconductor layer on the base substrate, and a p-type semiconductor layer on the n-type semiconductor layer, the n-type semiconductor layer being constituted from a group III nitride crystal containing an n-type impurity, the p-type semiconductor layer being constituted from a group III nitride crystal containing Mg as a p-type impurity, and the n-type semiconductor layer and the p-type semiconductor layer constituting a PN junction, or
a PI junction structure including an i-type semiconductor layer on the base substrate, and the p-type semiconductor layer on the i-type semiconductor layer, the i-type semiconductor layer being constituted from a group III nitride, and the i-type semiconductor layer and the p-type semiconductor layer constituting a PI junction,
wherein Mg concentration in the n-type semiconductor layer or the i-type semiconductor layer is less than 1×10¹⁶ cm⁻³, and
Fe concentration at an interface of the PN junction or the PI junction is 2×10¹⁵cm⁻³ or less.

(Supplementary description 2) The semiconductor stack according to Supplementary description 1, wherein Fe concentration in the n-type semiconductor layer and the i-type semiconductor layer is 2×10¹⁵ cm⁻³ or less.

(Supplementary description 3) The semiconductor stack according to Supplementary description 1 or 2, wherein C concentration in the n-type semiconductor layer, the i-type semiconductor layer, and the p-type semiconductor layer is less than 5×10¹⁵ cm⁻³.

(Supplementary description 4) The semiconductor stack according to any one of Supplementary descriptions 1 to 3, wherein
O concentration in the n-type semiconductor layer is less than 5×10¹⁵ cm⁻³,
B concentration in the n-type semiconductor layer is less than 1×10¹⁵ cm⁻³, and
concentration of the n-type impurity in the n-type semiconductor layer is 5×10¹⁴ cm⁻³ or more.

(Supplementary description 5) The semiconductor stack according to any one of Supplementary descriptions 1 to 3, wherein
Si concentration in the i-type semiconductor layer is less than 1×10¹⁵ cm⁻³,
O concentration in the i-type semiconductor layer is less than 5×10¹⁵ cm⁻³, and
B concentration in the i-type semiconductor layer is less than 1×10¹⁵ cm⁻³.

(Supplementary description 6) The semiconductor stack according to any one of Supplementary descriptions 1 to 5, wherein
Si concentration in the p-type semiconductor layer is less than 1×10¹⁵ cm⁻³,
B concentration in the p-type semiconductor layer is less than 1×10¹⁵ cm⁻³,
O concentration in the p-type semiconductor layer is less than 5×10¹⁵ cm⁻³, and
F concentration in the p-type semiconductor layer is less than 4×10¹³ cm⁻³.

(Supplementary description 7) The semiconductor stack according to any one of Supplementary descriptions 1 to 5, wherein
Si concentration in the p-type semiconductor layer is less than 1×10¹⁵ cm⁻³,
B concentration in the p-type semiconductor layer is less than 1×10¹⁵ cm⁻³,
O concentration in the p-type semiconductor layer is less than 5×10¹⁵ cm⁻³, and
F concentration in the p-type semiconductor layer is 1×10¹⁴ cm⁻³ or more.

(Supplementary description 8) A method of producing a semiconductor stack, the method including:
(a) placing a base substrate in a first space and placing an Mg source in a gas generator placed in a second space different (partitioned) from the first space, the first space being for crystal growth, the first and second spaces being spaces inside a reaction vessel provided in a hydride vapor phase epitaxy apparatus; then
(b) performing either (b1) supplying, to the base substrate in the first space, a halide of a group III element and a nitriding agent while also supplying an n-type impurity-containing gas, and growing an n-type semiconductor layer on the base substrate, the n-type semiconductor layer being constituted from a group III nitride crystal containing an n-type impurity, or (b2) supplying, to the base substrate in the first space, a halide of a group III element and a nitriding agent, and growing an i-type semiconductor layer on the base substrate, the i-type semiconductor layer being constituted from a group III nitride crystal; and
(c) supplying, to the base substrate in the first space, a halide of a group III element and a nitriding agent while also supplying an Mg-containing gas from a nozzle provided at a downstream end of a gas supply pipe connected to a downstream side of the gas generator, the Mg-containing gas being generated either by supplying a halogen-containing gas to the Mg source in the gas generator and reacting between the halogen-containing gas and the Mg source, or by vaporizing the Mg source in the gas generator, and growing a p-type semiconductor layer on the base substrate, the p-type semiconductor layer being constituted from a group III nitride crystal containing Mg,
wherein the generation of the Mg-containing gas is started before the start of the (c) (for example, during execution of the (b) or before the start of the (b)), and the Mg-containing gas generated before the start of the (c) is discharged to outside the reaction vessel through a vent pipe connected to the gas supply pipe without passing through the first space, and
the Mg-containing gas generated during execution of the (c) is supplied to the base substrate in the first space from the nozzle by switching a flow path of the Mg-containing gas by controlling a flow-path switching valve provided at a site where the gas supply pipe is connected with the vent pipe.

(Supplementary description 9) A hydride vapor phase epitaxy apparatus including:
a reaction vessel including, on an inside of the reaction vessel, a first space in which a base substrate is placed and crystal growth is performed and a second space that is heated to a temperature different from a temperature of the first space;
a gas generator, which is placed in the second space and in which a dopant source is placed;
a gas supply pipe connected to a downstream end of the gas generator;
a nozzle connected to a downstream end of the gas supply pipe, the nozzle being configured to supply a dopant-containing gas generated in the gas generator toward the base substrate in the first space;
a vent pipe connected to the gas supply pipe;
a flow-path switching valve placed in the second space, the flow-path switching valve being configured to switch a flow path of the dopant-containing gas generated in the gas generator so as to discharge the dopant-containing gas to outside the reaction vessel through the vent pipe without passing through the first space; and
a controller configured to control the flow-path switching valve,
wherein inside the reaction vessel, there are provided, as flow paths of the dopant-containing gas generated in the gas generator, a first flow path in which the dopant-containing gas is supplied to the base substrate in the first space through the gas supply pipe and the nozzle, and a second flow path in which the dopant-containing gas is discharged to outside the reaction vessel through the gas supply pipe and the vent pipe without passing through the first space, and
the controller is configured to control the flow-path switching valve to switch between the first flow path and the second flow path.

(Supplementary description 10) The hydride vapor phase epitaxy apparatus according to Supplementary description 9, wherein, when performing a process of supplying, to the base substrate in the first space, a halide of a group III element and a nitriding agent while also supplying, to the base substrate in the first space through the first flow path, the Mg-containing gas generated in the gas generator to grow a p-type semiconductor layer constituted from a group III nitride crystal containing Mg on the base substrate,
the controller controls the flow-path switching valve such that the generation of the Mg-containing gas is started before the start of the process, and the Mg-containing gas generated before the start of the process is discharged to outside of the reaction vessel through the second flow path, and at the start of the process, the flow path of the Mg-containing gas is switched from the second flow path to the first flow path while keeping the generation of the Mg-containing gas continued without stopping.

(Supplementary description 11) The hydride vapor phase epitaxy apparatus according to Supplementary description 9, wherein
the flow-path switching valve is constituted from a member comprising any one from among alumina, silicon carbide, graphite, pyrolytic graphite, and boron nitride.

### REFERENCE SINGS LIST

1 Semiconductor stack
10 Base substrate
20 PN junction structure
20A PI junction structure
22 n-type semiconductor layer
24 p-type semiconductor layer
26 i-type semiconductor layer

What is claimed is

1. A semiconductor stack comprising:
a base substrate; and
a PN junction structure comprising an n-type semiconductor layer on the base substrate, and a p-type semiconductor layer on the n-type semiconductor layer, the n-type semiconductor layer being constituted from a group III nitride crystal containing an n-type impurity, the p-type semiconductor layer being constituted from a group III nitride crystal containing Mg as a p-type impurity, and the n-type semiconductor layer and the p-type semiconductor layer constituting a PN junction, or
a PI junction structure comprising an i-type semiconductor layer on the base substrate, and the p-type semiconductor layer on the i-type semiconductor layer, the i-type semiconductor layer being constituted from a group III nitride, and the i-type semiconductor layer and the p-type semiconductor layer constituting a PI junction,
wherein Mg concentration in the n-type semiconductor layer or the i-type semiconductor layer is less than 1×10¹⁶ cm⁻³, and
Fe concentration at an interface of the PN junction or the PI junction is 2×10¹⁵ cm⁻³ or less.

2. The semiconductor stack according to claim 1, wherein Fe concentration in the n-type semiconductor layer and the i-type semiconductor layer is 2×10¹⁵ cm⁻³ or less.

3. The semiconductor stack according to claim 1, wherein C concentration in the n-type semiconductor layer, the i-type semiconductor layer, and the p-type semiconductor layer is less than 5×10¹⁵ cm⁻³.

4. The semiconductor stack according to claim 1, wherein
O concentration in the n-type semiconductor layer is less than 5×10¹⁵ cm⁻³,
B concentration in the n-type semiconductor layer is less than 1×10¹⁵ cm⁻³, and
concentration of the n-type impurity in the n-type semiconductor layer is 5×10¹⁴ cm⁻³ or more.

5. The semiconductor stack according to claim 1, wherein
Si concentration in the i-type semiconductor layer is less than 1×10¹⁵ cm⁻³,
O concentration in the i-type semiconductor layer is less than 5×10¹⁵ cm⁻³, and
B concentration in the i-type semiconductor layer is less than 1×10¹⁵ cm⁻³.

6. The semiconductor stack according to claim 1, wherein
Si concentration in the p-type semiconductor layer is less than 1×10¹⁵ cm⁻³,
B concentration in the p-type semiconductor layer is less than 1×10¹⁵ cm⁻³,
O concentration in the p-type semiconductor layer is less than 5×10¹⁵ cm⁻³, and
F concentration in the p-type semiconductor layer is less than 4×10¹³ cm⁻³.

7. The semiconductor stack according to claim 1, wherein
Si concentration in the p-type semiconductor layer is less than 1×10¹⁵ cm⁻³,
B concentration in the p-type semiconductor layer is less than 1×10¹⁵ cm⁻³,
O concentration in the p-type semiconductor layer is less than 5×10¹⁵ cm⁻³, and
F concentration in the p-type semiconductor layer is 1×10¹⁴ cm⁻³ or more.

8. A method of producing a semiconductor stack, the method comprising:
(a) placing a base substrate in a first space and placing an Mg source in a gas generator placed in a second space different from the first space, the first space being for crystal growth, the first and second spaces being spaces inside a reaction vessel provided in a hydride vapor phase epitaxy apparatus; then
(b) performing either (b1) supplying, to the base substrate in the first space, a halide of a group III element and a nitriding agent while also supplying an n-type impurity-containing gas, and growing an n-type semiconductor layer on the base substrate, the n-type semiconductor layer being constituted from a group III nitride crystal containing an n-type impurity, or (b2) supplying, to the base substrate in the first space, a halide of a group III element and a nitriding agent, and growing an i-type semiconductor layer on the base substrate, the i-type semiconductor layer being constituted from a group III nitride crystal; and
(c) supplying, to the base substrate in the first space, a halide of a group III element and a nitriding agent while also supplying an Mg-containing gas from a nozzle provided at a downstream end of a gas supply pipe connected to a downstream side of the gas generator, the Mg-containing gas being generated either by supplying a halogen-containing gas to the Mg source in the gas generator and reacting between the halogen-containing gas and the Mg source, or by vaporizing the Mg source in the gas generator, and growing a p-type semiconductor layer on the base substrate, the p-type semiconductor layer being constituted from a group III nitride crystal containing Mg,
wherein the generation of the Mg-containing gas is started before the start of the (c), and the Mg-containing gas generated before the start of the (c) is discharged to outside the reaction vessel through a vent pipe connected to the gas supply pipe without passing through the first space, and
the Mg-containing gas generated during execution of the (c) is supplied to the base substrate in the first space from the nozzle by switching a flow path of the Mg-containing gas by controlling a flow-path switching valve provided at a site where the gas supply pipe is connected with the vent pipe.

9. A hydride vapor phase epitaxy apparatus comprising:
a reaction vessel including, on an inside of the reaction vessel, a first space in which a base substrate is placed and crystal growth is performed and a second space that is heated to a temperature different from a temperature of the first space;
a gas generator, which is placed in the second space and in which a dopant source is placed;
a gas supply pipe connected to a downstream end of the gas generator;
a nozzle connected to a downstream end of the gas supply pipe, the nozzle being configured to supply a dopant-containing gas generated in the gas generator toward the base substrate in the first space;
a vent pipe connected to the gas supply pipe;
a flow-path switching valve placed in the second space, the flow-path switching valve being configured to switch a flow path of the dopant-containing gas generated in the gas generator so as to discharge the dopant-containing gas to outside the reaction vessel through the vent pipe without passing through the first space; and
a controller configured to control the flow-path switching valve,
wherein inside the reaction vessel, there are provided, as flow paths of the dopant-containing gas generated in the gas generator, a first flow path in which the dopant-containing gas is supplied to the base substrate in the first space through the gas supply pipe and the nozzle, and a second flow path in which the dopant-containing gas is discharged to outside the reaction vessel through the gas supply pipe and the vent pipe without passing through the first space, and
the controller is configured to control the flow-path switching valve to switch between the first flow path and the second flow path.
